(19) United States
(12) Patent Application Publication
(10) Pub. No.: US 2026/0143251 A1
(43) Pub. Date: May 21, 2026

(54) IMAGE SENSING DEVICE

(71) Applicant: SK hynix Inc., Icheon-si (KR)

(72) Inventor: Dong Ho HA, Icheon-si (KR)

(21) Appl. No.: 19/276,481

(22) Filed: Jul. 22, 2025

(30) Foreign Application Priority Data
Nov. 19, 2024 (KR) 10-2024-0165088

(51) Int. Cl. H04N 25/59; H04N 25/773; H10F 39/00

(52) U.S. Cl. CPC H04N 25/59; H04N 25/773; H10F 39/8037

(57) ABSTRACT

Image sensing devices are disclosed. In an embodiment, an image sensing device includes a first diode and a second diode configured to adjust a total storage capacity of a floating diffusion region; and a conversion gain transistor configured to selectively connect the first diode to the floating diffusion region, allowing the image sensing device to achieve a desired total storage capacity and a corresponding conversion gain.

### CROSS-REFERENCE TO RELATED APPLICATION

This patent document claims the priority and benefits of Korean patent application No. 10-2024-0165088, filed on Nov. 19, 2024, the disclosure of which is incorporated herein by reference in its entirety as part of the disclosure of this patent document.

### TECHNICAL FIELD

The technology and embodiments disclosed in this patent document generally relate to an image sensing device capable of detecting light.

### BACKGROUND

An image sensing device can capture optical images by converting light into electrical signals using a photosensitive semiconductor material that reacts to light. With advancements in industries such as automotive, medical, computer and communication industries, the demand for high-performance image sensing devices is growing across various fields, such as smartphones, digital cameras, game machines, IoT (Internet of Things), robots, security cameras and medical micro cameras.

The image sensing device may be roughly divided into charge coupled device (CCD) image sensing devices and complementary metal oxide semiconductor (CMOS) image sensing devices. CCD image sensing devices offer a better image quality, but they tend to consume more power and are larger as compared to CMOS image sensing devices. CMOS image sensing devices are smaller in size and consume less power than CCD image sensing devices. Furthermore, CMOS image sensing devices are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

The dynamic range of an image captured by a CMOS image sensing device is defined as the ratio between the brightest and darkest pixel values within the image. An image with a wider dynamic range than the standard dynamic range (SDR) processed by electronic devices is generally referred to as a high dynamic range (HDR) image.

### SUMMARY

Various embodiments of the disclosed technology relate to an image sensing device that can generate an HDR image with improved quality.

In an embodiment of the disclosed technology, an image sensing device may include: a pixel array including a plurality of pixels configured to generate an electrical signal in response to incident light, wherein each of the plurality of pixels includes: a photoelectric conversion element configured to generate photocharges in response to the incident light; a floating diffusion region configured to receive and store the photocharges generated by the photoelectric conversion element; a first diode configured to receive a first bias voltage, wherein a capacitance of the first diode is adjusted based on the first bias voltage; a conversion gain transistor configured to selectively connect the floating diffusion region to the first diode; and a second diode connected to the floating diffusion region configured to receive a second bias voltage, wherein a capacitance of the second diode is adjusted based on the second bias voltage.

In some implementations, the conversion gain transistor may electrically connect the floating diffusion region to the first diode in response to the conversion gain transistor being turned on; and electrically separate the floating diffusion region from the first diode in response to the conversion gain transistor being turned off.

In some implementations, the first and second bias voltages may include a reverse bias voltage that is applied to each of the first diode and the second diode, respectively.

In some implementations, as a magnitude of the reverse bias voltage applied to the first diode increases, a total storage capacity of the floating diffusion region may decrease.

In some implementations, as a magnitude of the reverse bias voltage applied to the second diode increases, a total storage capacity of the floating diffusion region may decrease.

In some implementations, the plurality of pixels may further include: a first pixel; and a second pixel having a longer exposure time than the first pixel. A conversion gain of the first pixel is greater than a conversion gain of the second pixel.

In some implementations, a magnitude of a reverse bias voltage applied to the first diode or the second diode of the first pixel may be greater than a magnitude of a reverse bias voltage applied to the first diode or the second diode of the second pixel.

In some implementations, the plurality of pixels may include first to fourth pixels. The pixel array may include: a central region including the first pixel; a horizontal edge region disposed at a first side of the central region along a horizontal line passing through the central region, and including the second pixel; a vertical edge region disposed at a second side of the central region along a vertical line passing through the central region, and including the third pixel; and a diagonal edge region disposed at a third side of the central region along a diagonal line passing through the central region, and including the fourth pixel.

In some implementations, the first bias voltage may include a reverse bias voltage applied to the first diode, and a magnitude of the reverse bias voltage applied to the first diode of the first pixel may be smaller than a magnitude of the reverse bias voltage applied to the first diode of the second pixel or the third pixel.

In some implementations, the second bias voltage may include a reverse bias voltage applied to the second diode, and a magnitude of the reverse bias voltage applied to the second diode of the first pixel may be smaller than a magnitude of the reverse bias voltage applied to the second diode of the second pixel or the third pixel.

In some implementations, the first and second bias voltages may include a first reverse bias voltage applied to the first diode and a second reverse bias voltage applied to the second diode, respectively; a magnitude of the first reverse bias voltage applied to the first diode of the first pixel may be smaller than a magnitude of the first reverse bias voltage applied to the first diode of the fourth pixel; and a magnitude of the second reverse bias voltage applied to the second diode of the first pixel may be smaller than a magnitude of the second reverse bias voltage applied to the second diode of the fourth pixel.

In another embodiment of the disclosed technology, an image sensing device may include: a pixel array including a plurality of pixels configured to generate an electrical signal by converting photocharges generated in response to incident light, wherein each of the plurality of pixels includes first and second diodes configured to adjust a conversion gain that determines a magnitude of the electrical signal corresponding to an amount of the photocharges; and a bias voltage generator configured to transmit a bias voltage to each of the first diode and the second diode.

In some implementations, each of the plurality of pixels may further include: a conversion gain transistor configured to selectively connect, to the first diode, a floating diffusion region configured store photocharges generated in response to the incident light, wherein the second diode of each of the plurality of pixels is connected to the floating diffusion region.

In some implementations, upon turning on the conversion gain transistor of each of the plurality of pixels, the conversion gain transistor may selectively connect the floating diffusion region to the first diode; and upon turning off the conversion gain transistor of each of the plurality of pixels is turned off, the conversion gain transistor may electrically separate the floating diffusion region from the first diode.

In some implementations, the bias voltage generator may transmit a reverse bias voltage to each of the first and second diodes. As a magnitude of the reverse bias voltage increases, the conversion gain may increase, and as a magnitude of the reverse bias voltage decreases, the conversion gain may decrease.

In some implementations, the plurality of pixels may include first to fourth pixels. The pixel array may include: a central region including the first pixel; a horizontal edge region disposed at a first side of the central region along a horizontal line passing through the central region, and including the second pixel; a vertical edge region disposed at a second side of the central region along a vertical line passing through the central region, and including the third pixel; and a diagonal edge region disposed at a third side of the central region along a diagonal line passing through the central region, and including the fourth pixel.

In some implementations, the bias voltage generator may apply a stronger reverse bias voltage to the first diode of either the second pixel or the third pixel than a reverse bias voltage applied to the first diode of the first pixel.

In some implementations, the bias voltage generator may apply a stronger reverse bias voltage to the second diode of either the second pixel or the third pixel than a reverse bias voltage applied to the second diode of the first pixel.

In some implementations, the bias voltage generator may apply a stronger reverse bias voltage to the first diode of the fourth pixel than a reverse bias voltage applied to the first diode of the first pixel; and may apply a stronger reverse bias voltage to the second diode of the fourth pixel than a reverse bias voltage applied to the second diode of the first pixel.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example of an image sensing device based on some embodiments of the disclosed technology.

FIG. 2 is an example circuit diagram illustrating a pixel included in a pixel array shown in FIG. 1 based on some embodiments of the disclosed technology.

FIG. 3 is a cross-sectional view illustrating an example of the circuit diagram of FIG. 2 based on some embodiments of the disclosed technology.

FIG. 4 is a graph illustrating an example of current-voltage characteristics of diodes based on some embodiments of the disclosed technology.

FIG. 5 is a graph illustrating an example of capacitance-voltage characteristics of diodes based on some embodiments of the disclosed technology.

FIG. 6A is a graph illustrating a change in the total storage capacity of a floating diffusion region (FD) in FIG. 2 in response to bias voltages respectively applied to the first and second diodes based on some embodiments of the disclosed technology.

FIG. 6B shows example conditions for the first to seventh curves (61-67) shown in FIG. 6A based on some embodiments of the disclosed technology.

FIG. 7 is a graph illustrating an example of the change in the signal-to-noise ratio (SNR) in relation to the change in the total storage capacity shown in FIG. 6A based on some embodiments of the disclosed technology.

FIG. 8A is a timing diagram illustrating an example of circuit operations when the total storage capacity of the floating diffusion region (FD) in FIG. 2 has the first storage capacity of FIG. 6A based on some embodiments of the disclosed technology.

FIG. 8B is a timing diagram illustrating an example of circuit operations when the total storage capacity of the floating diffusion region (FD) in FIG. 2 has the second storage capacity of FIG. 6A based some embodiments of the disclosed technology.

FIG. 9A is a timing diagram illustrating an example of circuit operations when the total storage capacity of the floating diffusion region (FD) in FIG. 2 has the third storage capacity of FIG. 6A based on some embodiments of the disclosed technology.

FIG. 9B is a timing diagram illustrating an example of circuit operations when the total storage capacity of the floating diffusion region (FD) of FIG. 2 has the fourth storage capacity of FIG. 6A based on some embodiments of the disclosed technology.

FIG. 10 is a timing diagram illustrating an example of a dual conversion gain operation for a circuit in which the total storage capacity of the floating diffusion region (FD) in FIG. 2 has the second and third storage capacities of FIG. 6A based on some embodiments of the disclosed technology.

FIGS. 11A and 11B illustrate example signal lines applied to a plurality of pixels located in a pixel array by the bias voltage generator shown in FIG. 1 based on some embodiments of the disclosed technology.

### DETAILED DESCRIPTION

This patent document provides embodiments and examples of an image sensing device capable of detecting light that may be used in configurations to substantially address one or more technical or engineering issues and to mitigate limitations or disadvantages encountered in some image sensing devices in the art. Some embodiments of the disclosed technology relate to an image sensing device capable of generating an HDR image with improved quality. In recognition of the issues above, the embodiments of the disclosed technology may provide an image sensing device having various conversion gains. The image sensing device according to the embodiments of the disclosed technology may reduce unnecessary fluctuations in pixel signals due to changes in conversion gain when setting various conversion gains for generating HDR images.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

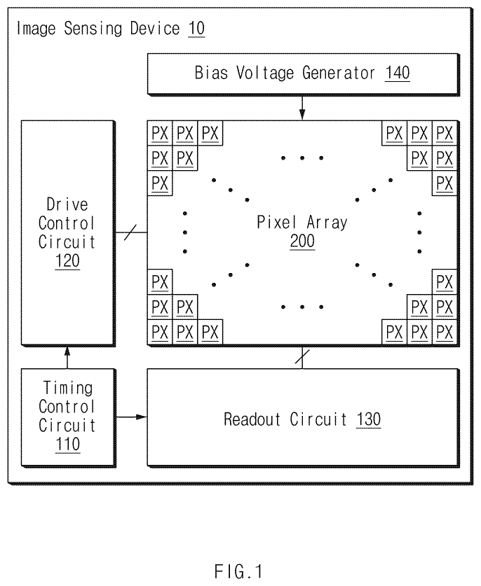

FIG. 1 is a schematic diagram illustrating an example of an image sensing device 10 based on some embodiments of the disclosed technology.

Referring to FIG. 1, the image sensing device 10 may include a timing control circuit 110, a drive control circuit 120, a pixel array 200, a readout circuit 130, and a bias voltage generator 140. The constituent components of the image sensing device 10 illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light. For example, the image sensing device 10 may be a Complementary Metal Oxide Semiconductor (CMOS) image sensor configured to convert incident light into an electrical signal.

The timing control circuit 110 may generate a timing signal for controlling the operation of the image sensing device 10. For example, the timing control circuit 110 may drive pixels (PXs) of the pixel array 200 using the timing signal. The timing control circuit 110 may select and control pixels (PXs) included in at least one row line from among a plurality of row lines of the pixel array 200. The timing control circuit 110 may generate a row selection signal to select at least one row from among the plurality of rows.

The drive control circuit 120 may sequentially enable a pixel reset signal and a transfer signal for pixels (PX) corresponding to at least one selected row. Accordingly, an analog reference signal and an image signal generated by each of the pixels (PXs) of the selected row may be sequentially transmitted to the readout circuit 130. The reference signal may be an electrical signal provided to the readout circuit 130 when a floating diffusion region (FD) of each pixel is reset to a power-supply voltage (VDD). The image signal may be an electrical signal provided to the readout circuit 130 when photocharges generated by each pixel are accumulated in the floating diffusion region (FD). The reference signal indicating unique pixel noise of each pixel, and the image signal indicating the intensity of incident light may be collectively referred to as a pixel signal as necessary.

The pixel array 200 may include a plurality of pixels (PXs) arranged in rows and columns. In one example, the plurality of pixels (PXs) can be arranged in a two-dimensional (2D) pixel array including rows and columns. In another example, the plurality of pixels (PXs) can be arranged in a three-dimensional (3D) pixel array. The plurality of pixels may convert an optical signal into an electrical signal on a pixel basis or a pixel group basis, and may output a pixel signal. Here, the pixels in a pixel group of the pixel array 200 may share at least certain internal circuitry. The pixel array 200 may receive driving signals including a row selection signal, a pixel reset signal, a transfer signal, etc. from the drive control circuit 120. Upon receiving the driving signals, corresponding imaging pixels in the pixel array 200 may be activated to perform the operations corresponding to the row selection signal, the pixel reset signal, and the transfer signal.

The readout circuit 130 may use the correlated double sampler (CDS) to remove undesired offset values of pixels known as the fixed pattern noise. In one example, the correlated double sampler (CDS) may remove the undesired offset value of pixels by comparing pixel output voltages obtained before and after photocharges generated by incident light are accumulated in the floating diffusion region (FD) so that only pixel output voltages based on the incident light can be measured. The readout circuit 130 may sequentially sample and hold voltage levels of the reference signal and the image signal, which are provided to each of a plurality of column lines from the pixel array 200. That is, the readout circuit 130 may sample and hold the voltage levels of the reference signal and the image signal which correspond to each of the columns of the pixel array 200. The readout circuit 130 may convert a correlated double sampler (CDS) signal, which is an analog signal for each column, into a digital signal, and may output the digital signal for each column. The readout circuit 130 may temporarily hold image data for each column, and may output the image data to, for example, an image processing device (not shown).

The bias voltage generator 140 may apply a bias voltage to each circuit component whose capacitance varies with bias, such as diode in the plurality of pixels (PXs) included in the pixel array 200. For example, the bias voltage may adjust the capacity of the floating diffusion region (FD) of each of the plurality of pixels (PXs) based on the voltage level. The bias voltage may have various values. For example, the value of the bias voltage may vary depending on the operation mode of the image sensing device 10. In some implementations, the bias voltage generator 140 may apply, for example, a negative voltage to each circuit component (e.g., diode) of the pixels (PXs) so that each circuit component (e.g., diode) of the pixels (PXs) is in a reverse-biased state, but the disclosed technology is not limited thereto.

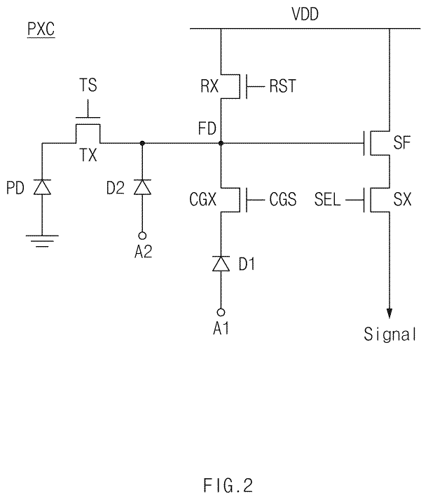

FIG. 2 is an example circuit diagram (PXC) illustrating a pixel included in the pixel array 200 shown in FIG. 1 based on some embodiments of the disclosed technology. As will be explained below, in some implementations, the bias voltage generator 140 may apply anode voltages (e.g., A1 and A2) to diodes that are connected to a floating diffusion region (FD) and a conversion gain transistor (CGX) in a pixel.

Referring to FIGS. 1 and 2, a unit pixel (PX) may correspond to one of the pixels (PXs) included in the pixel array 200 of FIG. 1. The unit pixel (PX) may generate a pixel signal (e.g., a reference signal and an image signal described in FIG. 1) in response to incident light. The unit pixel (PX) may include a photoelectric conversion element (PD), a transfer transistor (TX), a floating diffusion region (FD), a reset transistor (RX), a source follower transistor (SF), a selection transistor (SX), a conversion gain transistor (CGX), a first diode (D1), and a second diode (D2).

The photoelectric conversion element (PD) may generate photocharges corresponding to the intensity of incident light.

The transfer transistor (TX) may be connected between the photoelectric conversion element (PD) and the floating diffusion region (FD). The transfer transistor (TX) may transfer photocharges generated by the photoelectric conversion element (PD) to the floating diffusion region (FD). For example, when the transfer transistor (TX) is turned on, a channel through which photocharges can move may be formed between the photoelectric conversion element (PD) and the floating diffusion region (FD). Through the channel, the photocharges generated by the photoelectric conversion element (PD) may move to the floating diffusion region (FD). When the transfer transistor (TX) is turned off, the channel is not formed, and the movement of photocharges between the photoelectric conversion element (PD) and the floating diffusion region (FD) may be blocked.

A gate of the transfer transistor (TX) may receive a transfer signal (TS). For example, the transfer signal (TS) may be transmitted from the drive control circuit 120 to the gate of the transfer transistor (TX). When the transfer signal (TS) has a high level (e.g., a voltage level for turning on the transfer transistor TX or a voltage level higher than a threshold voltage level of the gate of the transfer transistor TX), the transfer transistor (TX) may be turned on. When the transfer signal (TS) has a low level (e.g., a voltage level for turning off the transfer transistor TX or a voltage level lower than a threshold voltage level of the gate of the transfer transistor TX), the transfer transistor (TX) may be turned off.

The floating diffusion region (FD) may store photocharges generated by the photoelectric conversion element (PD). The floating diffusion region (FD) may have intrinsic capacitance (hereinafter referred to as FD capacitance).

The reset transistor (RX) may be connected between the floating diffusion region (FD) and the power-supply voltage (VDD). The reset transistor (RX) may reset a voltage level of the floating diffusion region (FD). For example, when the reset transistor (RX) is turned on, a pixel reset operation in which the voltage level of the floating diffusion region (FD) is reset to the power-supply voltage (VDD) may be performed.

The gate of the reset transistor (RX) may receive a reset signal (RST). For example, the reset signal (RST) may be transmitted from the drive control circuit 110 to the gate of the reset transistor (RX). When the reset signal (RST) has a high level (e.g., a voltage level for turning on the reset transistor RX or a voltage level higher than a threshold voltage level of the gate of the reset transistor RX), the reset transistor (RX) may be turned on. When the reset signal (RST) has a low level (e.g., a voltage level for turning off the reset transistor RX or a voltage level lower than the threshold voltage level of the gate of the reset transistor RX), the reset transistor (RX) may be turned off.

A first diode (D1) may have a first capacitance. A cathode of the first diode (D1) may be connected to the conversion gain transistor (CGX). An anode of the first diode (D1) may receive a first anode voltage (A1) from the bias voltage generator 140. The first capacitance may vary when the magnitude of the first anode voltage (A1) varies.

When the conversion gain transistor (CGX) is turned on, the cathode of the first diode (D1) may become electrically connected to the floating diffusion region (FD). When the first anode voltage (A1) is greater than the voltage of the floating diffusion region (FD), the first anode voltage (A1) is a forward bias voltage applied to the first diode (D1). When the magnitude of the forward bias voltage applied to the first diode (D1) decreases, the first capacitance may decrease. When the magnitude of the forward bias voltage applied to the first diode (D1) increases, the first capacitance may increase.

When the first anode voltage (A1) is lower than the voltage of the floating diffusion region (FD), the first anode voltage (A1) is a reverse bias voltage applied to the first diode (D1). When the magnitude (or absolute value) of the reverse bias voltage applied to the first diode (D1) increases, the first capacitance may decrease. In this case (the reverse bias voltage case), the cathode voltage is higher than the anode voltage, and the magnitude of the reverse bias voltage may increase as the cathode voltage becomes higher than the anode voltage. When the magnitude of the reverse bias voltage applied to the first diode (D1) decreases, the first capacitance may increase.

A second diode (D2) may have a second capacitance. A cathode of the second diode (D2) may be connected to the floating diffusion region (FD). For example, an anode of the second diode (D2) may receive a second anode voltage (A2) from the bias voltage generator 140. The second capacitance may vary when the magnitude of the second anode voltage (A2) varies.

When the second anode voltage (A2) is greater than the voltage of the floating diffusion region (FD), a forward bias voltage may be applied to the second diode (D2). When the magnitude of the forward bias voltage applied to the second diode (D2) decreases, the second capacitance may decrease. When the magnitude of the forward bias voltage applied to the second diode (D2) increases, the second capacitance may increase.

When the second anode voltage (A2) is lower than the voltage of the floating diffusion region (FD), the second anode voltage (A2) is a reverse bias voltage applied to the second diode (D2). When the magnitude of the reverse bias voltage applied to the second diode (D2) increases, the second capacitance may decrease. When the magnitude of the reverse bias voltage applied to the second diode (D2) decreases, the second capacitance may increase.

The conversion gain transistor (CGX) may be connected to the floating diffusion region (FD). The conversion gain transistor (CGX) may act as a switch that changes the conversion gain when converting photocharges stored in the floating diffusion region (FD) into an electrical signal. The conversion gain may refer to a conversion ratio in the process of converting the voltage generated by the photocharges stored in the floating diffusion region (FD) into an electrical signal by a source follower transistor (SF).

The conversion gain transistor (CGX) may selectively connect the first diode (D1) to the floating diffusion region (FD). When the conversion gain transistor (CGX) is turned on, the first diode (D1) and the floating diffusion region (FD) may be connected to each other. When the conversion gain transistor (CGX) is turned off, the first diode (D1) and the floating diffusion region (FD) may be electrically isolated from each other.

The gate of the conversion gain transistor (CGX) may receive a conversion gain signal (CGS). For example, the conversion gain signal (CGS) may be transmitted from the drive control circuit 120 to the gate of the conversion gain transistor (CGX). When the conversion gain signal (CGS) has a high level (e.g., a voltage level for turning on the conversion gain transistor CGX or a voltage level higher than a threshold voltage level of the gate of the conversion gain transistor CGX), the conversion gain transistor (CGX) may be turned on. When the conversion gain signal (CGS) has a low level (e.g., a voltage level for turning off the conversion gain transistor CGX or a voltage level lower than a threshold voltage level of the gate of the conversion gain transistor CGX), the conversion gain transistor (CGX) may be turned off.

The total storage capacity (hereinafter referred to as C_{T}) of the floating diffusion region (FD) may be calculated by, for example, Equations 1 and 2 below.

$${C}_{T} = {C}_{FD} + {C}_{D 1} + {C}_{D 2} \qquad [ Equation l ]$$

$${C}_{T} = {C}_{FD} + {C}_{D 2} \qquad [ Equation 2 ]$$

In Equations 1 and 2, C_{T} is the total storage capacity of the floating diffusion region (FD), C_{FD} is intrinsic capacitance of the floating diffusion region (FD), C_{D1} is the first capacitance, and C_{D2} is the second capacitance.

When the conversion gain transistor (CGX) is turned on, the total storage capacity (C_{T}) can be determined from Equation 1. When the conversion gain transistor (CGX) is turned off, the total storage capacity (C_{T}) can be determined from Equation 2.

When the floating diffusion region (FD), the first diode (D1), and the second diode (D2) are connected in parallel to each other, Equation 1 or Equation 2 may be satisfied. The pixel circuit (PXC) of FIG. 2 may also be designed so that the floating diffusion region (FD), the first diode (D1), and the second diode (D2) are connected in parallel to each other.

When the conversion gain transistor (CGX) is turned on, the conversion gain transistor (CGX) electrically connects the floating diffusion region (FD) to the first diode (D1), and the total storage capacity (C_{T}) may satisfy Equation 1. When the conversion gain transistor (CGX) is turned off, the conversion gain transistor (CGX) electrically isolates the floating diffusion region (FD) and the first diode (D1) from each other, and the total storage capacity (C_{T}) may satisfy Equation 2.

The conversion gain transistor (CGX) selectively connects the first diode (D1) to the floating diffusion region (FD), so that the image sensing device implemented based on some embodiments of the disclosed technology may set a larger range of the total storage capacity (C_{T}) of the floating diffusion region (FD) for each pixel.

The first diode (D1) may have a variable first capacitance according to the sign and magnitude of the first bias voltage (BV1) received from the bias voltage generator 140, and when the conversion gain transistor (CGX) is turned on, the first diode (D1) may change the total storage capacity of the floating diffusion region (FD).

The second diode (D2) may have a variable second capacitance depending on the sign and magnitude of the second bias voltage (BV2) received from the bias voltage generator 140, and since the second diode (D2) is directly connected to the floating diffusion region (FD), the diode (D2) may change the total storage capacity (C_{T}) of the floating diffusion region (FD).

The source follower transistor (SF) may be connected between a power-supply voltage (VDD) and a selection transistor (SX). The source follower transistor (SF) may output an electrical signal according to the amount of photocharges accumulated in the floating diffusion region (FD) to the selection transistor (SX). The gate of the source follower transistor (SF) may be connected to the floating diffusion region (FD). The voltage of the floating diffusion region (FD) according to the photocharges accumulated in the floating diffusion region (FD) may be proportional to a conversion gain. The relationship between the voltage generated by the photocharges stored in the floating diffusion region (FD) and the total storage capacity (C_{T}) may satisfy, for example, a conventional relationship denoted by “V=Q/C.” That is, in a situation where the amount of photocharges stored in the floating diffusion region (FD) is the same, if the total storage capacity (C_{T}) of the floating diffusion region (FD) decreases, the voltage of the floating diffusion region (FD) increases, so that the magnitude of the electrical signal to be output by the source follower transistor (SF) to the selection transistor (SX) may increase. Conversely, if the total storage capacity (C_{T}) of the floating diffusion region (FD) increases, the voltage of the floating diffusion region (FD) decreases, so that the magnitude of the electrical signal to be output by the source follower transistor (SF) to the selection transistor (SX) may decrease.

The selection transistor (SX) may be connected to the source follower transistor (SF) to output a pixel signal. For example, the selection transistor (SX) of a pixel that is not being read out may be turned off, and the selection transistor (SX) of a pixel that is being read out may be turned on.

The gate of the selection transistor (SX) may receive a row selection signal (SEL). For example, the row selection signal (SEL) may be transmitted from the drive control circuit 110 to the gate of the selection transistor (SX). When the row selection signal (SEL) has a high level (e.g., a voltage level for turning on the selection transistor (SX) or a voltage level higher than a threshold voltage level of the gate of the selection transistor (SX)), the selection transistor (SX) may be turned on. When the row selection signal (SEL) has a low level (e.g., a voltage level for turning off the selection transistor (SX) or a voltage level lower than a threshold voltage level of the gate of the selection transistor (SX)), the selection transistor (SX) may be turned off.

When the selection transistor (SX) is turned on, the selection transistor (SX) may output an electrical signal generated by the source follower transistor (SF) to the readout circuit 130. For example, the electrical signal may be transmitted from the selection transistor (SX) to the readout circuit 130.

A series of operations of the pixel circuit (PXC) for outputting a pixel signal of the unit pixel (PX) may include, for example, a pixel reset operation, a first readout operation, a photocharge accumulation operation, and a second readout operation.

In the pixel reset operation, to read out the reference signal, the pixel circuit (PXC) may turn on the reset transistor (RX), may connect the reset transistor (RX) to the power-supply voltage (VDD) of the floating diffusion region (FD), and may reset a voltage of the floating diffusion region (FD) to the power-supply voltage (VDD). In some implementations, the pixel circuit (PXC) may also turn on the transfer transistor (TX) to reset the voltage of the photoelectric conversion element (PD).

When the floating diffusion region (FD) is completely reset, in a first readout operation, the selection transistor (SX) may be turned on so that an electrical signal (e.g., a reference signal) corresponding to the voltage of the floating diffusion region (FD) generated by the source follower transistor (SF) may be output to, for example, the readout circuit 130. The total storage capacity (C_{T}) of the floating diffusion region (FD) when outputting the reference signal may be the same as the total storage capacity (C_{T}) of the floating diffusion region (FD) when outputting the image signal to be described below.

To read out the image signal, in the photocharge storage operation, photocharges generated by the photoelectric conversion element (PD) in response to incident light while the transfer transistor (TX) is turned off may be accumulated in the photoelectric conversion element (PD) without moving to the floating diffusion region (FD). In some implementations, when it is necessary to adjust the total storage capacity (C_{T}) of the floating diffusion region (FD), this can be achieved by modifying the voltage level of the second anode voltage (A2) applied to the anode of the second diode (D2) and/or the voltage level of the first anode voltage (A1) applied to the anode of the first diode (D1) when the conversion gain transistor (CGX) is turned on.

After a predetermined period of time, during a second readout operation, the transfer transistor (TX) may be turned on, and photocharges generated by the photoelectric conversion element (PD) may move to the floating diffusion region (FD). When the photocharges are stored in the floating diffusion region (FD), the source follower transistor (SF) may output the electrical signal (e.g., image signal) in response to the voltage of the floating diffusion region (FD). In the second readout operation, the selection transistor (SX) may also be turned on, and the electrical signal output from the source follower transistor (SF) may be output to the readout circuit 130.

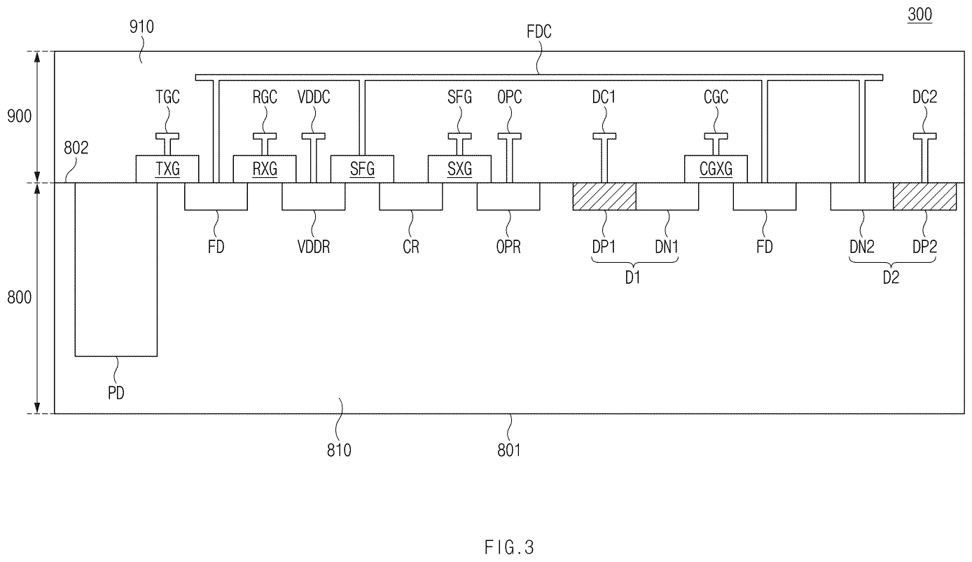

FIG. 3 is a cross-sectional view illustrating an example of the circuit diagram of FIG. 2 based on some embodiments of the disclosed technology.

Referring to FIGS. 2 and 3, the cross-section 300 may include a photoelectric conversion layer 800 and an electrical interconnect layer 900.

The photoelectric conversion layer 800 may include a photoelectric conversion element (PD), a floating diffusion region (FD), a power-supply voltage region (VDDR), a common region (CR), an output region (OPR), a first diode (D1), a second diode (D2), and a semiconductor region 810. The photoelectric conversion layer 800 may include a back surface 801 upon which incident light is incident, and a front surface 802 facing or opposite to the back surface 801. For example, the photoelectric conversion layer 800 may include a semiconductor material (e.g., silicon (Si), silicon germanium (SiGe), etc.).

The photoelectric conversion element (PD) may generate photocharges in response to light incident upon the back surface 801. In some implementations, the photoelectric conversion element (PD) may be located closer to the front surface 802 than to the back surface 801. For example, the photoelectric conversion element (PD) may be arranged to be in contact with the front surface 802. The photoelectric conversion element (PD) may include impurities of a first conductivity type (e.g., N-type). At least a portion of the photoelectric conversion element (PD) may overlap the transfer gate (TXG).

The floating diffusion region (FD) may be arranged to be spaced apart from the photoelectric conversion element (PD). The floating diffusion region (FD) may be located closer to the front surface 802 than to the back surface 801. For example, the floating diffusion region (FD) may be arranged to be in contact with the front surface 802. The floating diffusion region (FD) may be a doped region including impurities of the first conductivity type. The floating diffusion region (FD) may include a plurality of doped regions. The floating diffusion regions (FD) that are spaced apart from each other may be electrically connected through a single electrical interconnect line.

The power voltage region (VDDR) may be arranged to be spaced apart from the floating diffusion region (FD). The power voltage region (VDDR) may be located closer to the front surface 802 than to the back surface 801. For example, the power voltage region (VDDR) may be arranged to be in contact with the front surface 802. The power voltage region (VDDR) may be a doped region including impurities of the first conductive type. The power voltage region (VDDR) may be a region to which a power-supply voltage is applied. At least a portion of the power voltage region (VDDR) may overlap at least one of the reset gate (RXG) and the source follower gate (SFG).

The common region (CR) may be arranged to be spaced apart from the floating diffusion region (FD). The common region (CR) may be arranged to be in contact with the front surface 802 while located between the source follower gate (SFG) and the selection gate (SXG). The output region (OPR) may be arranged to be spaced apart from the floating diffusion region (FD), the power-supply voltage region (VDDR), and the photoelectric conversion element (PD). The output region (OPR) may be located closer to the front surface 802. For example, the output region (OPR) may be arranged to be in contact with the front surface 802. The output region (OPR) may be a doped region including impurities of the first conductivity type. At least a portion of the output region (OPR) may overlap the selection gate (SXG).

The first diode (D1) may be arranged to be spaced apart from the floating diffusion region (FD), the power-supply voltage region (VDDR), the photoelectric conversion element (PD), and the output region (OPR). The first diode (D1) may be located closer to the front surface 802. For example, the first diode (D1) may be arranged to be in contact with the front surface 802. The first diode (D1) may include a first N-type region (DN1) and a first P-type region (DP1).

The first N-type region (DN1) may be a region corresponding to the cathode of the first diode (D1). The first N-type region (DN1) may be a doped region including impurities of the first conductivity type. The first P-type region (DP1) may be a region corresponding to the anode of the first diode (D1). The first P-type region (DP1) may be a doped region including impurities of the second conductivity type (e.g., P-type). The first N-type region (DN1) and the first P-type region (DP1) may contact each other and may form a PN junction. At least a portion of the first N-type region (DN1) may overlap the conversion gain gate (CGXG).

The second diode (D2) may be arranged to be spaced apart from the floating diffusion region (FD), the power-supply voltage region (VDDR), the photoelectric conversion element (PD), the output region (OPR), and the first diode (D1). The second diode (D2) may be located closer to the front surface 802. For example, the second diode (D2) may be arranged to be in contact with the front surface 802. The second diode (D2) may include a second N-type region (DN2) and a second P-type region (DP1).

The second N-type region (DN2) may be a region corresponding to the cathode of the second diode (D2). The second N-type region (DN2) may be a doped region including impurities of the second conductivity type. The second P-type region (DP2) may be a region corresponding to the anode of the second diode (D2). The second P-type region (DP2) may be a doped region including impurities of the second conductivity type. The second N-type region (DN2) and the second P-type region (DP2) may contact each other, and may form a PN junction. The second N-type region (DN2) may be electrically connected to the floating diffusion region (FD) through electrical interconnect lines.

The semiconductor region 810 may be the remaining region of the photoelectric conversion layer 800 that contacts each of the photoelectric conversion element (PD), the floating diffusion region (FD), the power-supply voltage region (VDDR), the output region (OPR), the first diode (D1) and the second diode (D2). The semiconductor region 810 may be, for example, a doping region including impurities of the second conductivity type. The semiconductor region 810 may have a lower impurity concentration of the second conductivity type than the first P-type region (DP1) and the second P-type region (DP2).

The electrical interconnect layer 900 may include a transfer gate (TXG), a transfer gate contact interconnect line (TGC), a reset gate (RXG), a reset gate contact interconnect line (RGC), a source follower gate (SFG), a selection gate (SXG), a selection gate contact interconnect line (SGC), a conversion gain gate (CGXG), a conversion gain contact interconnect line (CGC), an output node contact interconnect line (OPC), a first diode contact interconnect line (DC1), a second diode contact interconnect line (DC2), a floating diffusion node contact interconnect line (FDC), and an insulation region 910. For example, the electrical interconnect layer 900 may contact the front surface 802.

The transfer gate (TXG) may overlap each of the photoelectric conversion element (PD) and the floating diffusion region (FD). The transfer gate (TXG) may be the gate of the transfer transistor (TX). When the transfer transistor (TX) is turned on, a channel serving as a charge transfer path may be formed in a space between the photoelectric conversion element (PD) and the floating diffusion region (FD).

The transfer gate contact interconnect line (TGC) may transmit a transfer signal (TS) to the transfer gate (TXG).

The reset gate (RXG) may overlap each of the floating diffusion region (FD) and the power-supply voltage region (VDDR). The reset gate (RXG) may be the gate of the reset transistor (RX). When the reset transistor (RX) is turned on, a channel serving as a charge transfer path may be formed in a space between the floating diffusion region (FD) and the power-supply voltage region (VDDR).

The reset gate contact interconnect line (RGC) may transmit a reset signal (RST) to the reset gate (RXG).

The source follower gate (SFG) may overlap the power-supply voltage region (VDDR). The source follower gate (SFG) may be the gate of the source follower transistor (SF). The source follower gate (SFG) may be electrically connected to the floating diffusion region (FD) through a predetermined electrical interconnect line (e.g., a floating diffusion node contact interconnect line FDC).

The selection gate (SXG) may overlap the source follower gate (SFG) in the same doped region (e.g., a floating diffusion region FD). The selection gate (SXG) may overlap an output region (OPR). The selection gate (SXG) may be the gate of the selection transistor (SX).

The selection gate contact interconnect line (SGC) may transmit a row selection signal (SEL) to the selection gate (SXG).

The conversion gain gate (CGXG) may overlap each of the floating diffusion region (FD) and the first diode (D1). The conversion gain gate (CGXG) may be the gate of the conversion gain transistor (CGX) (see FIG. 2). When the conversion gain transistor (CGX) is turned on, a channel serving as a charge transfer path may be formed between the first N-type region (DN1) and the floating diffusion region (FD).

The conversion gain contact interconnect line (CGC) may transmit a conversion gain signal (CGS) to the conversion gain gate (CGXG).

The output node contact interconnect line (OPC) may contact the output region (OPR). The output node contact interconnect line (OPC) may be an electrical interconnect through which an electrical signal (e.g., a reference signal or an image signal) is output from the selection transistor (SX) to a readout circuit 130 (see FIG. 1).

The first diode contact interconnect line (DC1) may contact the first diode (D1). For example, the first diode contact interconnect line (DC1) may contact the first P-type region (DP1). The first diode contact interconnect line (DC1) may transmit the first anode voltage (A1) to the first P-type region (DP1).

The second diode contact interconnect line (DC2) may contact the second diode (D2). For example, the second diode contact interconnect line (DC2) may contact the second P-type region (DP2). The second diode contact interconnect line (DC2) may transmit the second anode voltage (A2) to the second P-type region (DP2).

The floating diffusion node contact interconnect line (FDC) may contact the floating diffusion region (FD), the second diode (D2), and the source follower gate (SFG). The floating diffusion node contact interconnect line (FDC) may electrically connect the floating diffusion region (FD) to the source follower gate (SFG). The floating diffusion node contact interconnect line (FDC) may electrically connect the floating diffusion region (FD) to the second diode (D2) (e.g., the second P-type region DP2).

Each of the transfer gate (TXG), the reset gate (RXG), the source follower gate (SFG), the selection gate (SXG), and the conversion gain gate (CGXG) may include a gate electrode layer and a gate insulation layer. Each of the gate electrode layers may include at least one of conductive materials, for example, polysilicon, polysilicon including impurities, a metal, a metal nitride, a metal silicide, and combinations thereof. Each of the gate insulation layers may include at least one of insulation materials, for example, silicon oxide, silicon nitride, germanium oxide, germanium nitride, hafnium oxide, zirconium oxide, aluminum oxide, and combinations thereof.

The insulation region 910 may electrically isolate the separated components including the above-described conductive materials. The insulation region 910 may include at least one of insulation materials, for example, silicon oxide, silicon nitride, germanium oxide, germanium nitride, hafnium oxide, zirconium oxide, aluminum oxide, and combinations thereof.

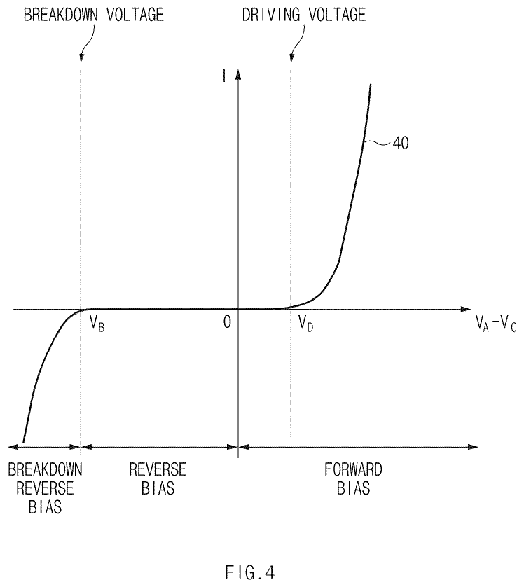

FIG. 4 is a graph illustrating an example of current-voltage characteristics of the diodes based on some embodiments of the disclosed technology.

Referring to FIG. 4, the current-voltage curve 40 is an example of a curve showing the magnitude of a current (I) according to a difference (hereinafter referred to as a bias voltage “V_{A}−V_{C}”) between the anode voltage (V_{A}) and the cathode voltage (V_{C}) of diodes (e.g., the first diode D1 and the second diode D2 including a PN junction as shown in FIG. 3).

The anode may refer to a region doped with P-type impurities, and the cathode may refer to a region doped with N-type impurities.

When the bias voltage (V_{A}−V_{C}) is greater than zero (0), a forward bias voltage is applied to the diode, and when the bias voltage (V_{A}−V_{C}) is less than zero (0), a reverse bias voltage is applied to the diode. As the absolute value of the bias voltage (V_{A}−V_{C}) increases, the magnitude of the voltage generated by the diode increases.

When a forward bias voltage (V_{A}−V_{C}>V_{D}) greater than or equal to the driving voltage (VD) having a forward bias is applied to the diode, current may flow through this diode. The driving voltage (VD) may have a value greater than or equal to a built-in voltage of the diode. When a reverse bias (V_{A}−V_{C}<V_{D}) greater than or equal to a breakdown voltage (VB) having a reverse bias is applied to the diode, current may flow through this diode.

On the other hand, when a forward bias voltage less than the driving voltage (VD) or a reverse bias voltage less than the breakdown voltage (VB) is applied to the diode, almost no current may flow through the diode.

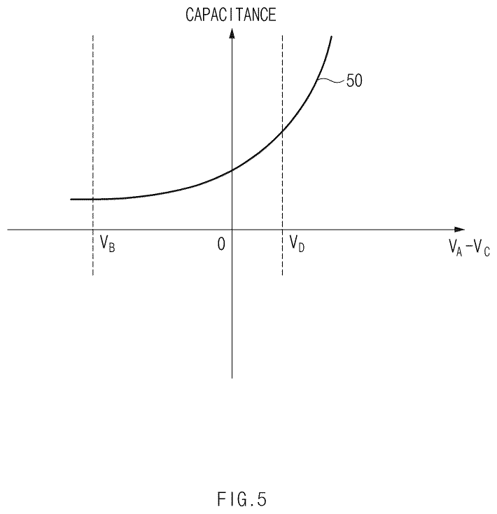

FIG. 5 is a graph illustrating an example of capacitance-voltage characteristics of diodes based on some embodiments of the disclosed technology.

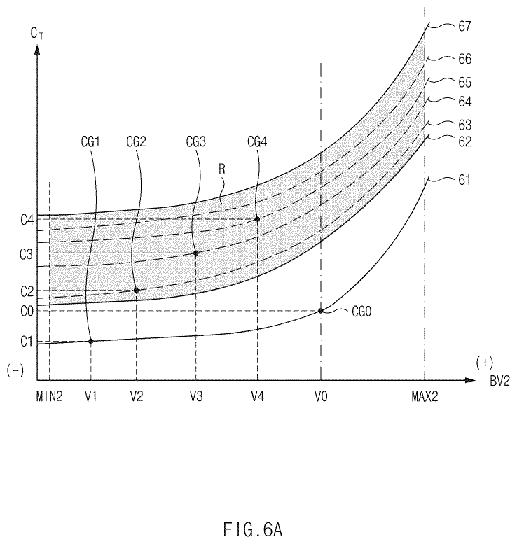

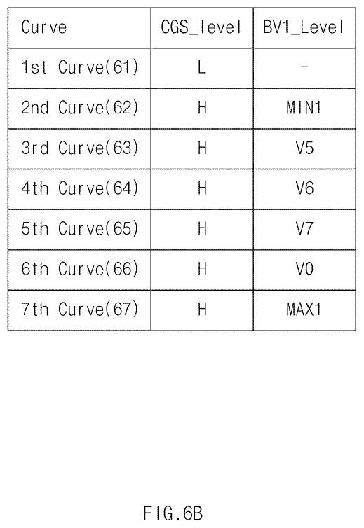

Referring to FIG. 5, the capacitance-voltage curve 50 is an exemplary curve showing the magnitude of capacitance according to the bias voltage (V_{A}−V_{C}) of the diode (e.g., the diode shown in FIG. 4). The relationship between the bias voltage (V_{A}−V_{C}) and the capacitance shown by the capacitance-voltage curve 50 may explain a change in total storage capacity (C_{T}) according to the first or second bias voltage (BV1, BV2) shown in FIG. 6A.

When the forward bias voltage is applied to the diode (V_{A}−V_{C}>0), the capacitance may decrease as the magnitude of the forward bias voltage decreases. When the reverse bias voltage is applied to the diode (V_{A}−V_{C}<0), the capacitance may decrease as the magnitude of the reverse bias voltage increases.

Hereinafter, examples in which the bias voltage (V_{A}−V_{C}) is in a range between the breakdown voltage (V_{B}) and the driving voltage (V_{D}) will be representatively described in detail.

FIG. 6A is a graph illustrating a change in the total storage capacity of the floating diffusion region (FD) in FIG. 2 in response to bias voltages (BV1, BV2) respectively applied to the first and second diodes (D1, D2) based on some embodiments of the disclosed technology.

FIG. 6B shows example conditions for the first to seventh curves (61-67) shown in FIG. 6A based on some embodiments of the disclosed technology.

Referring to FIGS. 2, 5, 6A and 6B, in the graph illustrated in FIG. 6A, the horizontal axis may represent a second bias voltage (BV2) applied to the second diode (D2). The second bias voltage (BV2) may represent a voltage obtained by subtracting the cathode voltage of the second diode (D2) from the anode voltage of the second diode (D2). The anode voltage of the second diode (D2) may be a voltage caused by the second anode voltage (A2). The cathode voltage of the second diode (D2) may be a voltage of the floating diffusion region (FD).

When the transfer transistor (TX) is turned on and photocharges move from the photoelectric conversion element (PD) to the floating diffusion region (FD), this transfer alters the amount of photocharges in the floating diffusion region (FD), which may lead to a change in the voltage of the floating diffusion region (FD). However, if the intrinsic capacitance of the floating diffusion region (FD) is sufficiently large, the change in the voltage of the floating diffusion region (FD) may be minimal. In some embodiments of the disclosed technology, an example case in which intrinsic capacitance of the floating diffusion region (FD) has a sufficiently large value so that the change in voltage is very small even when photocharges move from the photoelectric conversion element (PD) will hereinafter be described as a representative example.

The second bias voltage (BV2) may be a forward bias voltage when the second anode voltage (A2) has a voltage level greater than the voltage level of the floating diffusion region (FD). The second bias voltage (BV2) may be a reverse bias voltage in which the second anode voltage (A2) has a voltage level lower than the voltage level of the floating diffusion region (FD).

In the graph illustrated in FIG. 6A, the vertical axis represents the total storage capacity (C_{T}) of the floating diffusion region (FD). The total storage capacity (C_{T}) may satisfy Equation 1 or Equation 2.

The first bias voltage (BV1) represents a voltage obtained by subtracting the cathode voltage of the first diode (D1) from the anode voltage of the first diode (D1). The anode voltage of the first diode (D1) may be a voltage caused by the first anode voltage (A1). The cathode voltage of the first diode (D1) may be a voltage of the floating diffusion region (FD) under the condition that the conversion gain transistor (CGX) is turned on.

The first to seventh curves (61-67) may be examples of curves showing changes in the total storage capacity (C_{T}) according to the level of the conversion gain signal (CGS), the first bias voltage (BV1), and the second bias voltage (BV2).

The first bias voltage (BV1) may be a forward bias voltage when the first anode voltage (A1) has a voltage level greater than the voltage level of the floating diffusion region (FD) and the conversion gain transistor (CGX) is turned on. The first bias voltage (BV1) may be a reverse bias voltage when the first anode voltage (A1) has a voltage level less than the voltage level of the floating diffusion region (FD) and the conversion gain transistor (CGX) is turned on.

The first curve 61 represents an example case where the conversion gain signal (CGS) has a low level (L).

The first bias voltage (BV1) may have a voltage level between a first minimum bias voltage (MIN1) and a first maximum bias voltage (MAX1). For example, the second curve 62 represents an example case in which the conversion gain signal (CGS) has a high level and the first bias voltage (BV1) is the first minimum bias voltage (MIN1). The third curve 63 represents an example case in which the conversion gain signal (CGS) has a high level (H) and the first bias voltage (BV1) is a fifth voltage (V5). The fourth curve 64 represents an example case in which the conversion gain signal (CGS) has a high level (H) and the first bias voltage (BV1) is a sixth voltage (V6). The fifth curve 65 represents an example case in which the conversion gain signal (CGS) has a high level (H) and the first bias voltage (BV1) is a seventh voltage (V7). The sixth curve 66 represents an example case in which the conversion gain signal (CGS) has a high level (H) and the first bias voltage (BV1) is the eighth voltage (V0). The seventh curve 67 represents an example case in which the conversion gain signal (CGS) has a high level (H) and the first bias voltage (BV1) is the first maximum bias voltage (MAX1).

The first minimum bias voltage (MIN1) may be a reverse bias voltage having a smaller magnitude than the breakdown voltage of the first diode (D1). That is, the absolute value of the first minimum bias voltage (MIN1) may be smaller than the absolute value of the breakdown voltage. The first maximum bias voltage (MAX1) may be a forward bias voltage having a smaller magnitude than the driving voltage (see FIG. 4) of the first diode (D1).

The voltage may increase in the order of the fifth voltage (V5), the sixth voltage (V6), the seventh voltage (V7), and the eighth voltage (V0). In some embodiments, the eighth voltage (V0) may be a level of the first bias voltage (BV1) when the cathode voltage and the anode voltage of the first diode (D1) are at the same level. In this case, the fifth to seventh voltages (V5-V7) may be reverse bias voltages. The magnitude (absolute value) of the reverse bias voltage may be such that the fifth voltage (V5) may be greater than the sixth and seventh voltages (V6, V7), and the seventh voltage (V7) may be less than the fifth and sixth voltages (V5, V6).

The second bias voltage (BV2) may have a voltage level between a second minimum bias voltage (MIN2) and a second maximum bias voltage (MAX2).

The second minimum bias voltage (MIN2) may be a reverse bias voltage having a smaller magnitude (absolute value) than the breakdown voltage of the second diode (D2). That is, the breakdown voltage of the second diode (D2) may be located to the left of MIN2 on the graph. The second maximum bias voltage (MAX2) may be a forward bias voltage having a smaller magnitude than the driving voltage of the second diode (D2).

The second bias voltage (BV2) may have any one value from among the first voltage (V1), the second voltage (V2), the third voltage (V3), the fourth voltage (V4), and the eighth voltage (V0), without being limited thereto.

The second bias voltage (BV2) may increase in the order of the first voltage (V1), the second voltage (V2), the third voltage (V3), the fourth voltage (V4), and the eighth voltage (V0). The eighth voltage (V0) represents the second bias voltage (BV2) when the cathode voltage and the anode voltage of the second diode (D2) have the same level. In this case, the eighth voltage (V0) may have a value of zero volts (OV).

The cathode voltage of the first diode (D1) and the cathode voltage of the second diode (D2) may be equal to the voltage of the floating diffusion region (FD). In the example shown in FIG. 6A, each of the first to fourth voltages (V1-V4) may be a reverse bias voltage. Among the first to fourth voltages (V1-V4), the magnitude (absolute value) of the reverse bias voltage may be the largest for the first voltage (V1) and the smallest for the fourth voltage (V4).

When the first bias voltage (BV1) is a reverse bias voltage, the magnitude of the reverse bias voltage may decrease as the first anode voltage (A1) increases. When the first bias voltage (BV1) is a forward bias voltage, the magnitude of the forward bias voltage may increase as the first anode voltage (A1) increases.

When the second bias voltage (BV1) is a reverse bias voltage, the magnitude of the reverse bias voltage may decrease as the second anode voltage (A2) increases. When the second bias voltage (BV2) is a forward bias voltage, the magnitude of the forward bias voltage may increase as the second anode voltage (A2) increases.

Under the condition that the conversion gain transistor (CGX) is turned on and the second bias voltage (BV2) is maintained at a constant value, as the magnitude of the forward bias voltage of the first bias voltage (BV1) decreases or as the magnitude of the reverse bias voltage increases (from the upper portion 67 to the lower portion 62 on the graph), the first capacitance (C_{D1}) may decrease, and thus the total storage capacity (C_{T}) may decrease. For example, in a situation where the first bias voltage (BV1) is a reverse bias voltage, when the magnitude of the reverse bias voltage applied to the first diode (D1) increases, the total storage capacity (C_{T}) may decrease and the conversion gain may increase.

Under the condition that the conversion gain transistor (CGX) is turned off, or under the condition that the conversion gain transistor (CGX) is turned on and the first bias voltage (BV1) is maintained at a constant value, as the magnitude of the forward bias voltage of the second bias voltage (BV2) decreases or as the magnitude of the reverse bias voltage increases (from the right (+) to the left (−) on the graph), the second capacitance (C_{D2}) may decrease, and thus the total storage capacity (C_{T}) may decrease. For example, in a situation where the second bias voltage (BV2) is a reverse bias voltage, when the magnitude of the reverse bias voltage applied to the second diode (D2) increases, the total storage capacity (C_{T}) may decrease and the conversion gain may increase.

In the range of the storage capacity that can be used as the total storage capacity (C_{T}), in a situation where the conversion gain transistor (CGX) is turned off, the total storage capacity (C_{T}) may be minimized when the second bias voltage (BV2) is the second minimum bias voltage (MIN2). In a situation where the conversion gain transistor (CGX) is turned off, the total storage capacity (C_{T}) may be maximized when the second bias voltage (BV2) is the second maximum bias voltage (MAX2).

In the range of the storage capacity that can be used as the total storage capacity (C_{T}), in a situation where the conversion gain transistor (CGX) is turned on, the total storage capacity (C_{T}) may be minimized when the first bias voltage (BV1) is the first minimum bias voltage (MIN1) and the second bias voltage (BV2) is the second minimum bias voltage (MIN2). In a situation where the conversion gain transistor (CGX) is turned on, the total storage capacity (C_{T}) may be maximized when the first bias voltage (BV1) is the first maximum bias voltage (MAX1) and the second bias voltage (BV2) is the second maximum bias voltage (MAX2).

The larger the total storage capacity (C_{T}) of the floating diffusion region (FD), the smaller the conversion gain. The smaller the total storage capacity (C_{T}) of the floating diffusion region (FD), the larger the conversion gain.

The conversion gain of the unit pixel (PX) implemented based on an embodiment of the disclosed technology may be set to various levels. For example, each of the five levels of conversion gains that include an offset conversion gain (CG0) and the first to fourth conversion gains (CG1-CG4) illustrated in FIG. 6A may be an example of the conversion gain of the unit pixel (PX). The number of conversion gains that can be set for the unit pixel (PX) may be greater or less than five “5”. In addition, the level of the conversion gain may also vary depending on the embodiment. When the conversion gain signal (CGS) is at a low level and the second bias voltage (BV2) is the eighth voltage (V0) (e.g., OV), the total storage capacity (C_{T}) of the floating diffusion region (FD) is the offset storage capacity (C0), and the conversion gain when outputting a pixel signal (including the reference signal or the image signal described in FIG. 1) may be the offset conversion gain (CG0).

To set the conversion gain to the first conversion gain (CG1), the total storage capacity (C_{T}) may be set to the first storage capacity (C1). In an embodiment in which the total storage capacity (C_{T}) is set to the first storage capacity (C1), the conversion gain transistor (CGX) may be turned off (e.g., the conversion gain signal (CGS) has a low level) and the second bias voltage (BV2) is set to the first voltage (V1).

To set the conversion gain to the second conversion gain (CG2), the total storage capacity (C_{T}) may be set to the second storage capacity (C2). In an embodiment in which the total storage capacity (C_{T}) is set to the second storage capacity (C2), the conversion gain transistor (CGX) may be turned on (e.g., the conversion gain signal (CGS) has a high level), the first bias voltage (BV1) may be set to the fifth voltage (V5), and the second bias voltage (BV2) may be set to the second voltage (V2).

To set the conversion gain to the third conversion gain (CG3), the total storage capacity (C_{T}) may be set to the third storage capacity (C3). In an embodiment in which the total storage capacity (C_{T}) is set to the third storage capacity (C3), the conversion gain transistor (CGX) may be turned on (e.g., the conversion gain signal (CGS) has a high level), the first bias voltage (BV1) may be set to the sixth voltage (V6), and the second bias voltage (BV2) may be set to the third voltage (V3).

To set the conversion gain to the fourth conversion gain (CG4), the total storage capacity (C_{T}) may be set to the fourth storage capacity (C4). In an embodiment in which the total storage capacity (C_{T}) is set to the fourth storage capacity (C4), the conversion gain transistor (CGX) may be turned on (e.g., the conversion gain signal (CGS) has a high level), the first bias voltage (BV1) may be set to the seventh voltage (V7), and the second bias voltage (BV2) may be set to the fourth voltage (V4).

Since the image sensing device 10 (see FIG. 1) implemented based on an embodiment of the disclosed technology uses both the first diode (D1) and the second diode (D2), the range of the total storage capacity (C_{T}) and the conversion gain, each of which can be set, may be set wider.

In some implementations, when designing a plurality of pixels that detects the same color light and is adjacent to each other so that some pixels have relatively low conversion gains and the remaining pixels have relatively high conversion gains, the ratio of the lowest pixel value that the pixel can have and the largest pixel value that the pixel can have may increase, and the dynamic range of the image sensing device may increase.

Information on conditions (e.g., the level of the conversion gain signal (CGS), the first bias voltage (BV1), the second bias voltage (BV2), etc.) for setting the level of the conversion gain described above may be stored in a memory device (not shown). For example, the memory device may be a one-time programmable (OTP) memory included in the image sensing device 10 (see FIG. 1). In another example, the memory device may be a memory chip embedded in an image capture device such as a camera separately from the image sensing device 10 (see FIG. 1).

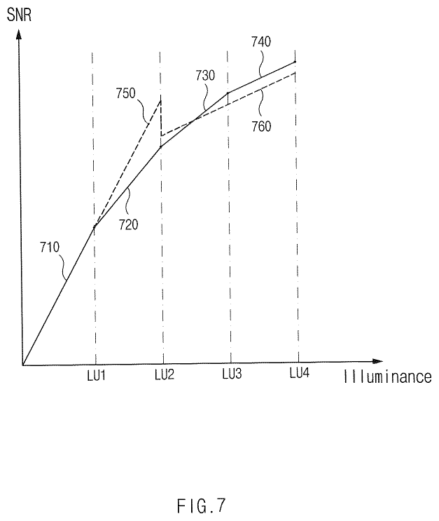

FIG. 7 is a graph illustrating an example of the change in the signal-to-noise ratio (SNR) in relation to the change in the total storage capacity (C_{T}) shown in FIG. 6A based on some embodiments of the disclosed technology.

Referring to FIG. 2, FIG. 6A, and FIG. 7, the horizontal axis may represent illuminance of incident light, and the vertical axis may represent the signal-to-noise ratio (SNR). The slopes of each line may represent conversion gains.

When changing the conversion gain, if the conversion gain after the change is much smaller than the conversion gain before the change (for example, if the change is from the first conversion gain CG1 to the fourth conversion gain CG4), the signal-to-noise ratio (SNR) may temporarily decrease.

For example, in a situation where illuminance of incident light is less than a first illuminance (LU1), when the unit pixel (PX) outputs a pixel signal with the first conversion gain (CG1), the signal-to-noise ratio (SNR) may increase along the first line 710. The first conversion gain (CG1) may be a conversion gain of the unit pixel (PX), for example, when the conversion gain signal (CGS) is set to a low level and the second bias voltage (BV2) is set to the first voltage (V1). However, the scope of the conditions for setting the first conversion gain (CG1) is not limited thereto.

In a situation where illuminance of incident light is greater than or equal to the first illuminance (LU1) and less than or equal to the second illuminance (LU2), when the unit pixel (PX) outputs a pixel signal with the first conversion gain (CG1), the signal-to-noise ratio (SNR) may increase along the fifth line 750.

In a situation where the illuminance of incident light reaches the second illuminance (LU2), changing the conversion gain of the unit pixel (PX) to the fourth conversion gain (CG4) may temporarily decrease the signal-to-noise ratio (SNR). When the conversion gain decreases rapidly, the degree of a decrease in the magnitude of the pixel signal relative to noise may increase, leading to a further temporary decrease in the signal-to-noise ratio (SNR).

In a situation where the illuminance of incident light is greater than or equal to the second illuminance (LU2), when the unit pixel (PX) outputs a pixel signal with the fourth conversion gain (CG4), the signal-to-noise ratio (SNR) may increase along the sixth line 760. The fourth conversion gain (CG4) may be a conversion gain of the unit pixel (PX), for example, when the conversion gain signal (CGS) is set to a high level, the first bias voltage (BV1) is set to the seventh voltage (V7), and the second bias voltage (BV2) is set to the fourth voltage (V4). The scope of the conditions for setting the fourth conversion gain (CG4) is not limited thereto.

On the other hand, when the conversion gain is gradually changed, the degree of a decrease in the magnitude of the pixel signal relative to noise is minimal, thereby minimizing or preventing a temporary decrease in the signal-to-noise ratio (SNR).

For example, in a situation where the illuminance of incident light is less than the first illuminance (LU1), outputting the pixel signal with the first conversion gain (CG1) may increase the signal-to-noise ratio (SNR) along the first line 710. The fourth conversion gain (CG4) may be a conversion gain of the unit pixel (PX), for example, when the conversion gain signal (CGS) is set to a low level and the second bias voltage (BV2) is set to the first voltage (V1). The scope of the conditions for setting the first conversion gain (CG1) is not limited thereto.

In a situation where the illuminance of incident light is greater than or equal to the first illuminance (LU1) and less than the second illuminance (LU2), changing the conversion gain from the first conversion gain (CG1) to the second conversion gain (CG2) may increase the signal-to-noise ratio (SNR) along the second line 720. The second conversion gain (CG2) may be a conversion gain of the unit pixel (PX), for example, when the conversion gain signal (CGS) is set to a high level, the first bias voltage (BV1) is set to the fifth voltage (V5), and the second bias voltage (BV2) is set to the second voltage (V2). The scope of the conditions for setting the second conversion gain (CG2) is not limited thereto.

In a situation where the illuminance of incident light is greater than or equal to the second illuminance (LU2) and less than the third illuminance (LU3), changing the conversion gain from the second conversion gain (CG2) to the third conversion gain (CG3) may increase the signal-to-noise ratio (SNR) along the third line 730. The third conversion gain (CG3) may be a conversion gain of the unit pixel (PX), for example, when the conversion gain signal (CGS) is set to a high level, the first bias voltage (BV1) is set to the sixth voltage (V6), and the second bias voltage (BV2) is set to the third voltage (V3). The scope of the conditions for setting the third conversion gain (CG3) is not limited thereto.

In a situation where the illuminance of incident light is greater than or equal to the third illuminance (LU3) and less than the fourth illuminance (LU4), changing the conversion gain from the third conversion gain (CG3) to the fourth conversion gain (CG4) may increase the signal-to-noise ratio (SNR) along the fourth line 740. The fourth conversion gain (CG4) may be a conversion gain of the unit pixel (PX), for example, when the conversion gain signal (CGS) is set to a high level, the first bias voltage (BV1) is set to the seventh voltage (V7), and the second bias voltage (BV2) is set to the fourth voltage (V4). The scope of the conditions for setting the fourth conversion gain (CG4) is not limited thereto.

When the conversion gain varies, variations in SNR may occur. Depending on how the conversion gain varies, both the magnitude of the output signal and the magnitude of noise may vary, leading to a temporary decrease in the SNR.

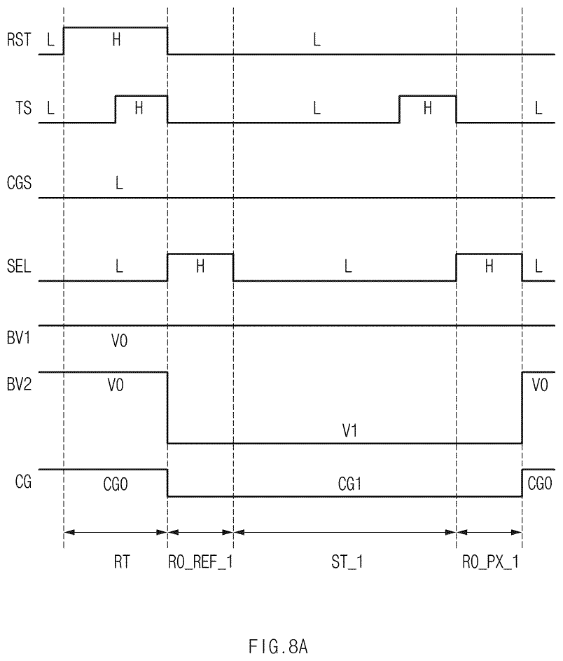

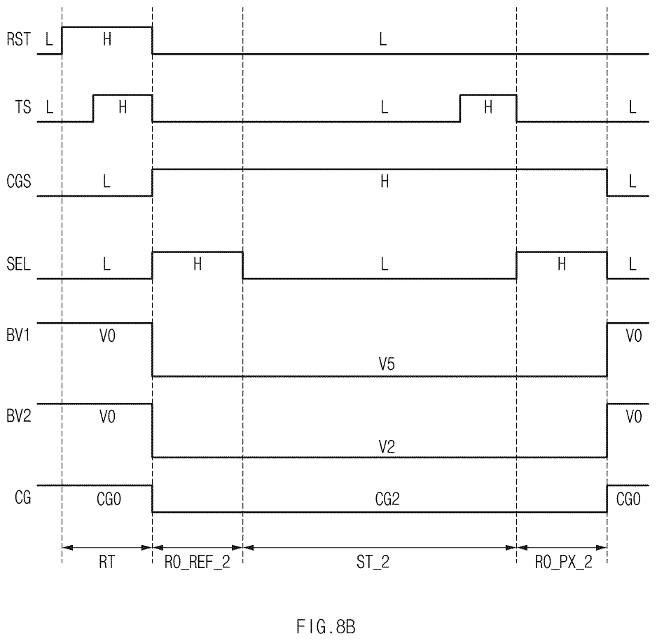

FIG. 8A is a timing diagram illustrating an example of circuit operations when the total storage capacity (C_{T}) of the floating diffusion region (FD) in FIG. 2 has the first storage capacity (C1) of FIG. 6A based on some embodiments of the disclosed technology.

The timing diagram of FIG. 8A may be an exemplary timing diagram for a pixel having a short exposure time in a low-illuminance environment from among pixels implemented based on some embodiments of the disclosed technology.

Referring to FIGS. 1, 2, 6A, and 8A, a reset period (RT) may be a period for resetting the voltage of the floating diffusion region (FD) to the power-supply voltage (VDD). When the reset period (RT) begins, the reset signal (RST) may transition from a low level to a high level. The reset signal (RST) may maintain a high level within the reset period (RT).

In the reset period (RT), each of the conversion gain signal (CGS) and the row selection signal (SEL) may have a low level.

In the reset period (RT), after a predetermined period of time from a transition time at which the transfer signal (TS) transitions from a low level to a high level, the transfer signal (TS) may transition back to a low level. While the transfer signal (TS) has a high level, the photoelectric conversion element (PD) may also be reset to the power-supply voltage (VDD).

Each of the first bias voltage (BV1) and the second bias voltage (BV2) may be set to the eighth voltage (V0). The first anode voltage (A) that causes the first bias voltage (BV1) to have the eighth voltage (V0) may be, for example, the power-supply voltage (VDD). The second anode voltage (A2) that causes the second bias voltage (BV2) to have the eighth voltage (V0) may be, for example, the power-supply voltage (VDD). When the reset signal (RST) changes from a high level to a low level, the reset period (RT) may end.

A reference signal readout period (RO_REF_1) following the reset period (RT) may be a period in which a reference signal of the unit pixel (PX) is output to the readout circuit 130. When the reference signal readout period (RO_REF_1) begins, the row selection signal (SEL) may transition from a low level to a high level. The row selection signal (SEL) may be maintained at a high level within the reference signal readout period (RO_REF_1).

In the reference signal readout period (RO_REF_1), each of the conversion gain signal (CGS), the transfer signal (TS), and the reset signal (RST) may be maintained at a low level.

The first bias voltage (BV1) may be maintained at the eighth voltage (V0). The second bias voltage (BV2) may have the first voltage (V1). Since the conversion gain signal (CGS) has a low level and the second bias voltage (BV2) is at the first voltage (V1), the total storage capacity (C_{T}) of the floating diffusion region (FD) may be the first storage capacity (C1), and the conversion gain of the unit pixel (PX) may be the first conversion gain (CG1). The reference signal obtained when the voltage level of the floating diffusion region (FD) is converted according to the first conversion gain (CG1) may be output to the readout circuit 130 by the selection transistor (SX) via the source follower transistor (SF).

Immediately after the transfer signal (TS) transitions from a high level to a low level, photocharges generated by the photoelectric conversion element (PD) may be accumulated in the photoelectric conversion element (PD). For example, during the reference signal readout period (RO_REF_1), photocharges generated by the photoelectric conversion element (PD) may be accumulated in the photoelectric conversion element (PD).

In an accumulation period (ST_1) following the reference signal readout period (RO_REF_1), only the row selection signal (SEL) transitions from a high level to a low level, and the levels of the respective signals may be maintained. In the accumulation period (ST_1), photocharges generated in response to incident light incident upon the photoelectric conversion element (PD) may be accumulated in the photoelectric conversion element (PD).

The accumulation period (ST_1) may be shorter (e.g., less than 0.01 seconds) in the short-exposure pixel than in the long-exposure pixel.

Before the accumulation period (ST_1) ends, the transfer signal (TS) may transition from a low level to a high level for a predetermined time and may then transition back to a low level. When the transfer signal (TS) has a high level within the accumulation period (ST_1), photocharges accumulated by the photoelectric conversion element (PD) may move to the floating diffusion region (FD) and stored therein.

An image signal readout period (RO_PX_1) following the accumulation period (ST_1) may be a period in which the image signal of the unit pixel (PX) is output to the readout circuit 130.

When the image signal readout period (RO_PX_1) begins, the row selection signal (SEL) may transition from a low level to a high level. Within the image signal readout period (RO_REF_1), the row selection signal (SEL) may be maintained at a high level.

In the image signal readout period (RO_PX_1), the image signal, which is an electrical signal corresponding to a voltage level caused by the photocharges stored in the floating diffusion region (FD), may be output to the readout circuit 130 by the selection transistor (SEL) through the source follower transistor (SF).

In the image signal readout period (RO_PX_1), each of the reset signal (RST) and the transfer signal TS may be maintained at a low level.

The conversion gain signal (CGS) may be maintained at a low level. The first bias voltage BV1 may also maintain the eighth voltage (V0). The second bias voltage (BV2) may remain at the first voltage V1. The total storage capacity (C_{T}) of the floating diffusion region (FD) may be a first storage capacity (C1), and the conversion gain of the unit pixel (PX) may be a first conversion gain (CG1).

When the unit pixel (PX) is a short-exposure pixel having a relatively short exposure time, the amount of photocharges generated by the photoelectric conversion element (PD) in the low-illuminance environment may be relatively smaller than the amount of photocharges generated by either the long-exposure pixel having a relatively long exposure time or the pixel used in the high-illuminance environment. Accordingly, when the conversion gain of the short-exposure pixel is set to be relatively high by setting the total storage capacity (C_{T}) of the short-exposure pixel to be relatively low, a deviation of the pixel signal with the long-exposure pixel may be reduced.

FIG. 8B is a timing diagram illustrating an example of circuit operations when the total storage capacity (C_{T}) of the floating diffusion region (FD) in FIG. 2 has the second storage capacity (C2) of FIG. 6A based some embodiments of the disclosed technology.

The following description will focus on differences between FIG. 8A and FIG. 8B.

The timing diagram of FIG. 8B may be an example timing diagram for a pixel having a long exposure time in the low-illuminance environment from among embodiments of the disclosed technology.

Referring to FIGS. 1, 2, 6A, 8A and 8B, the reset period (RT) may operate in substantially the same manner as in FIG. 8A.

The reference signal readout period (RO_REF_2) following the reset period (RT) may be a period in which the reference signal of the unit pixel (PX) is output to the readout circuit 130. When the reference signal readout period (RO_REF_1) begins, the row selection signal (SEL) may transition from a low level to a high level. The row selection signal (SEL) may be maintained at a high level within the reference signal readout period (RO_REF_2).

In the reference signal readout period (RO_REF_2), each of the transfer signal (TS) and the reset signal (RST) may be maintained at a low level. However, the conversion gain signal (CGS) may have a high level, unlike in FIG. 8A. As the conversion gain signal (CGS) has a high level, the conversion gain transistor (CGX) may be turned on.

The first bias voltage (BV1) may be at the fifth voltage (V5). The second bias voltage (BV2) may be at the second voltage (V2). Here, the total storage capacity (C_{T}) of the floating diffusion region (FD) may be the second storage capacity (C2). The conversion gain of the unit pixel (PX) may be the second conversion gain (CG2). A reference signal, which is an electrical signal corresponding to the voltage of the floating diffusion region (FD), may be output to the readout circuit 130 by the selection transistor (SX) after passing through the source follower transistor (SF) in response to the second conversion gain (CG2).

Immediately after the transfer signal (TS) transitions from a high level to a low level, photocharges generated by the photoelectric conversion element (PD) may be accumulated in the photoelectric conversion element (PD). For example, photocharges generated by the photoelectric conversion element (PD) during the reference signal readout period (RO_REF_2) may be accumulated in the photoelectric conversion element (PD).

In the accumulation period (ST_2) following the reference signal readout period (RO_REF_2), the levels of the respective signals may be almost equal to each other as compared to the accumulation period (ST_1) of FIG. 8A. The accumulation period (ST_2) may be longer (e.g., 0.01 seconds or more) in the long-exposure pixel than in the short-exposure pixel.

Before the accumulation period (ST_2) ends, the transfer signal (TS) may transition from a low level to a high level for a predetermined time and may then transition back to a low level. When the transfer signal (TS) has a high level within the accumulation period (ST_2), the photocharges generated by the photoelectric conversion element (PD) may move to the floating diffusion region (FD) and stored therein.

The image signal readout period (RO_PX_2) following the accumulation period (ST_2) may be a period in which the image signal of the unit pixel (PX) is output to the readout circuit 130.

When the image signal readout period (RO_PX_1) begins, the row selection signal (SEL) may transition from a low level to a high level. The row selection signal (SEL) may be maintained at a high level within the image signal readout period (RO_REF_2).

In the image signal readout period (RO_PX_1), the reset signal (RST) and the transfer signal (TS) may have a low level, and the conversion gain signal (CGS) may have a high level.

Unlike FIG. 8A, since the conversion gain signal (CGS) has a high level, the conversion gain transistor (CGX) may be turned on. The first bias voltage (BV1) may be at the fifth voltage (V5), and the second bias voltage (BV2) may be maintained at the second voltage (V2). The total storage capacity (C_{T}) of the floating diffusion region (FD) may be the second storage capacity (C2), and the conversion gain of the unit pixel (PX) may be the second conversion gain (CG2).

The electrical signal obtained when the voltage of the floating diffusion region (FD) is generated in response to the second conversion gain (CG) according to photocharges stored in the floating diffusion region (FD) may be an image signal. Here, the photocharges are generated by the photoelectric conversion element (PD), move to the floating diffusion region (FD), and are finally stored in the floating diffusion region (FD). Accordingly, the image signal may be output to the readout circuit 130 by the selection transistor (SX) through the source follower transistor (SF).

Although the embodiments disclosed in this document have disclosed comparative examples of short-exposure pixels and long-exposure pixels for convenience of description, the scope or spirit of the embodiments is not limited thereto. Even when the deviation of pixel signals between low-sensitivity pixels and high-sensitivity pixels is adjusted, the conversion gain of each pixel may be set differently as described above.

There may be various methods for arranging low-sensitivity pixels and high-sensitivity pixels in one pixel array. For example, if such pixels are designed differently to have different sizes of light reception regions, the sensitivities of the pixels can also be set differently.

The disclosed technology is not limited to reducing the deviation of pixel signals between pixels having different exposure times or different sensitivities. The disclosed technology can also be implemented in some embodiments to provide an image sensing device 10 having a large dynamic range that is designed to increase the deviation of pixel signals depending on the operation modes. In some implementations, the method for increasing the deviation of different pixel signals may include, for example, setting the conversion gains of the pixels differently.

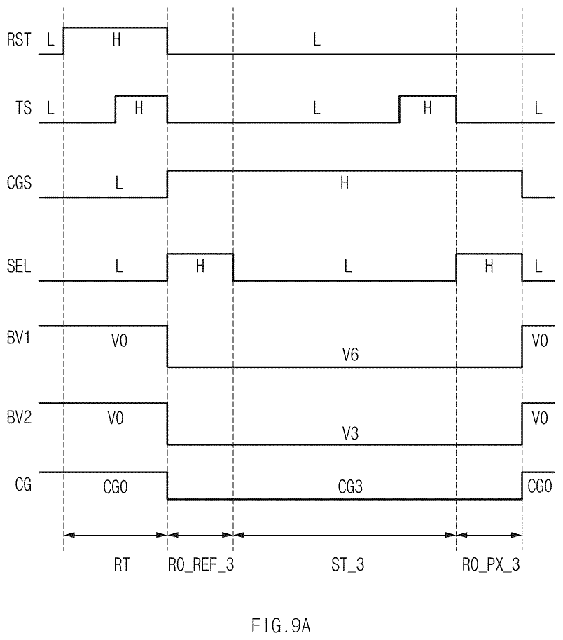

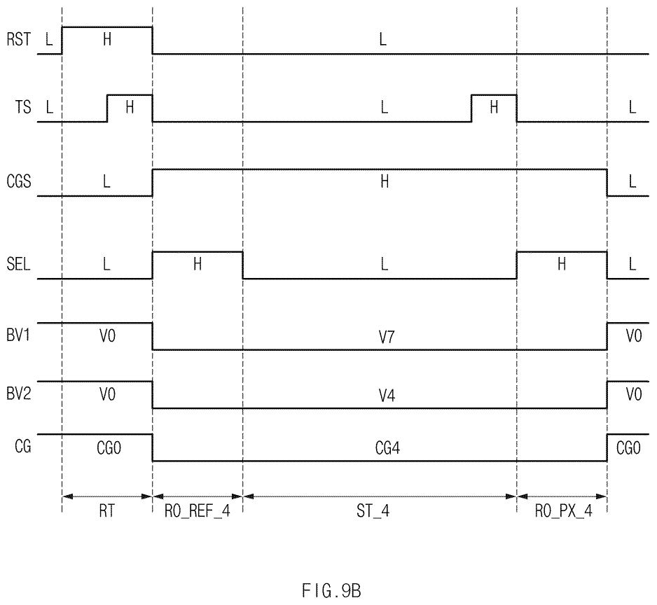

FIG. 9A is a timing diagram illustrating an example of circuit operations when the total storage capacity (C_{T}) of the floating diffusion region (FD) in FIG. 2 has the third storage capacity (C3) of FIG. 6A based on some embodiments of the disclosed technology.

The following description will focus on differences between FIG. 8A and FIG. 9A.

The reset signal (RST), the transfer signal (TS), and the row selection signal (SEL) shown in FIG. 9A may be controlled in substantially the same manner as in FIG. 8A.

In the reset period (RT), the floating diffusion region (FD) may be reset to the power-supply voltage (VDD).

In the reference signal readout period (RO_REF_3) following the reset period (RT), the reference signal of the unit pixel (PX) may be output with the third conversion gain (CG3).

When the reference signal readout period (RO_REF_3) begins, the conversion gain signal (CGS) may transition from a low level to a high level. In the reference signal readout period (RO_REF_3), the conversion gain signal (CGS) may be maintained at a high level. Since the conversion gain signal (CGS) maintains a high level, the conversion gain transistor (CGX) may remain turned on.

The first bias voltage (BV1) may be at the sixth voltage (V6). The second bias voltage (BV2) may be at the third voltage (V3). Here, the total storage capacity (C_{T}) of the floating diffusion region (FD) may be the third storage capacity (C3).

In the accumulation period (ST_3) following the reference signal readout period (RO_REF_3), the photoelectric conversion element (PD) may generate photocharges in response to incident light. Each of the reset signal (RST), the transfer signal (TS), and the row selection signal (SEL) of the accumulation period (ST_3) as shown in FIG. 9A may be controlled substantially in the same manner as in the accumulation period (ST_1) of FIG. 8A.

In the accumulation period (ST_3), the conversion gain signal (CGS) may be maintained at a high level. The first bias voltage (BV1) may maintain the sixth voltage (V6), and the second bias voltage (BV2) may maintain the third voltage (V3).

For example, the accumulation period (ST_3) of FIG. 9A may be less than 0.01 seconds, similar to the accumulation period (ST_1) of FIG. 8A.

The image signal readout period (RO_PX_3) following the accumulation period (ST_3) may output the image signal of the unit pixel (PX) to the readout circuit 130 at the third conversion gain (CG3).

In the image signal readout period (RO_PX_3), the reset signal (RST) may maintain a low level. The conversion gain signal (CGS) may maintain a high level. The row selection signal (SEL) may have a high level. The first bias voltage (BV1) may be at the sixth voltage (V6). The second bias voltage (BV2) may be at the third voltage (V3).

In the image signal readout period (RO_PX_3), during a predetermined time from the time at which the transfer signal (TS) is first switched from a high level to a low level to the other time at which the transfer signal (TS) is second switched from a high level to a low level, photocharges generated by the photoelectric conversion element (PD) may move to and be stored in the floating diffusion region (FD), and the voltage caused by the photocharges stored in the floating diffusion region (FD) may be output as the image signal by the third conversion gain (CG3). The image signal may be output to the readout circuit 130 by the selection transistor (SX) through the source follower transistor (SF).

FIG. 9B is a timing diagram illustrating an example of circuit operations when the total storage capacity (C_{T}) of the floating diffusion region (FD) in FIG. 2 has the fourth storage capacity (C4) of FIG. 6A based on some embodiments of the disclosed technology.

The following description will focus on differences between FIG. 8B and FIG. 9B.

The timing diagram of FIG. 9B may be an example timing diagram for a pixel having a long exposure time in the high-illuminance environment from among embodiments of the disclosed technology.

Referring to FIGS. 1, 2, 6A, 8B and 9B, the reset period (RT) may operate in substantially the same manner as in FIG. 8B.

The reset signal (RST) may transition from a low level to a high level when the reset period (RT) begins. The reset signal (RST) may transition from a high level to a low level when the reset period (RT) ends. The reset signal (RST) may maintain a low level in each of the reference signal readout period (RO_REF_4), the accumulation period (ST_4), and the image signal readout period (RO_PX_4).

The reference signal readout period (RO_REF_4) following the reset period (RT) may be a period in which the reference signal is output to the readout circuit 130.

When the reference signal readout period (RO_REF_4) begins, the row selection signal (SEL) may transition from a low level to a high level. When the reference signal readout period (RO_REF_4) ends, the row selection signal (SEL) may transition from a high level to a low level.

The row selection signal (SEL) may maintain a high level in each of the reference signal readout period (RO_REF_4) and the image signal readout period (RP_PX_4).

The conversion gain signal (CGS) may have a high level in the reference signal readout period (RO_REF_4). The conversion gain signal (CGS) may maintain a high level in each of the accumulation period (ST_4) and the image signal readout period (RO_PX_4).

The first bias voltage (BV1) may be at the seventh voltage (V7) in each of the reference signal readout period (RO_REF_4), the accumulation period (ST_4), and the image signal readout period (RO_PX_4).

The second bias voltage (BV2) may be at the fourth voltage (V4) in each of the reference signal readout period (RO_REF_4), the accumulation period (ST_4), and the image signal readout period (RO_PX_4).

In each of the reference signal readout period (RO_REF_4), the accumulation period (ST_4), and the image signal readout period (RO_PX_4), the total storage capacity (C_{T}) of the floating diffusion region (FD) may be the fourth storage capacity (C4), and the conversion gain of the unit pixel (PX) may be the fourth conversion gain (CG4).

The unit pixel (PX) may output an electrical signal corresponding to the voltage of the floating diffusion region (FD) as a reference signal at the fourth conversion gain (CG4).

In the accumulation period (ST_4), the photoelectric conversion element (PD) may generate and accumulate photocharges in response to incident light.

For example, the accumulation period (ST_4) may be 0.01 seconds or longer, like the accumulation period (ST_2) of FIG. 8B.

The transfer signal (TS) may first transition from a low level to a high level for the first time in the reset period (RT). The transfer signal (TS) may transition from a low level to a high level for the second time in the accumulation period (ST_4). Before the time point at which the row selection signal (SEL) transitions from a high level to a low level in the reference signal readout period (RO_REF_4), a first high level state of the transfer signal (TS) may transition to a low level. Before the time point at which the row selection signal (SEL) transitions from a high level to a low level in the image signal readout period (RO_PX_4), a second high level state of the transfer signal (TS) may transition to a low level.

The photoelectric conversion element (PD) may generate photocharges in response to incident light during a predetermined time from the time point at which the first high level state of the transfer signal (TS) transitions to a low level to the other time point at which the second high level state of the transfer signal (TS) transitions to a low level. The generated photocharges may move to the floating diffusion region (FD) and stored therein.

The image signal readout period (RO_PX_4) following the accumulation period (ST_4) may be a period in which the image signal of the unit pixel (PX) is output with the fourth conversion gain (CG4).

The voltage caused by the photocharges stored in the floating diffusion region (FD) may be output as the image signal according to the fourth conversion gain (CG4). When the image signal is output and the image signal readout period (RO_PX_4) ends, each of the row selection signal (SEL) and the conversion gain signal (CGS) may transition from a high level to a low level.

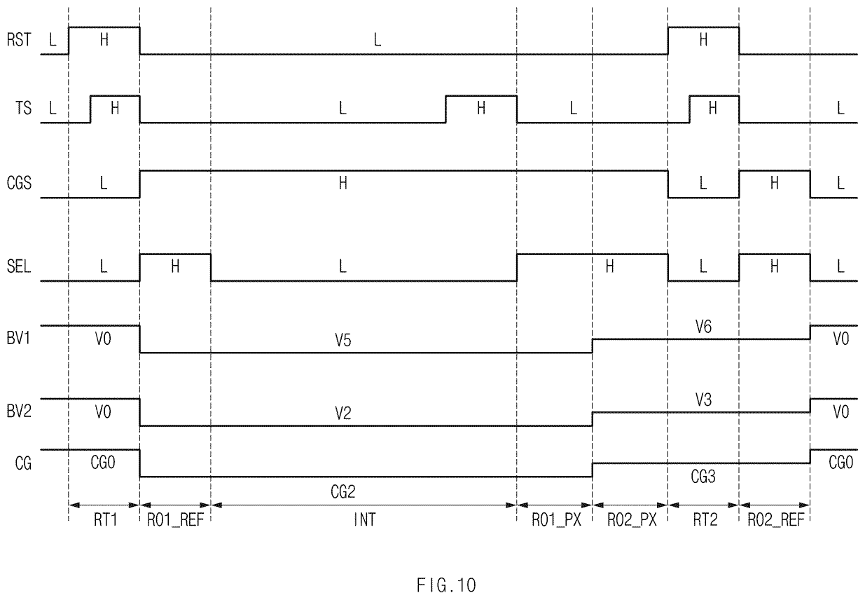

FIG. 10 is a timing diagram illustrating an example of a dual conversion gain (DCG) operation for a circuit in which the total storage capacity (C_{T}) of the floating diffusion region (FD) in FIG. 2 has the second and third storage capacities (C2, C3) of FIG. 6A based on some embodiments of the disclosed technology.

Referring to FIGS. 1, 2, 6A, 7, and 10, when the pixel signal of the unit pixel (PX) is output in a dual conversion gain (DCG) mode, the operation cycle of a pixel circuit (PXC) may include a first reset period (RT1), a first reference signal readout period (RO1_REF), an accumulation period (INT), a first image signal readout period (RO1_PX), a second image signal readout period (RO2_PX), a second reset period (RT2), and a second reference signal readout period (RO2_REF).

The reset signal (RST) may transition from a low level to a high level when the first reset period (RT1) begins. While the reset signal (RST) has a high level, the floating diffusion region (FD) of the unit pixel (PX) may be reset to the power-supply voltage (VDD). The reset signal (RST) may transition from a high level to a low level when the first reset period (RT1) ends.

The reset signal (RST) may maintain a low level in each of the first reference signal readout period (RO1_REF), the accumulation period (INT), the first image signal readout period (RO1_PX), and the second image signal readout period (RO1_PX).

The reset signal (RST) may transition from a low level to a high level again when the second reset period (RT) begins. While the reset signal (RST) has a high level, the floating diffusion region (FD) of the unit pixel (PX) may be reset to the power-supply voltage (VDD). The reset signal (RST) may transition from a high level to a low level when the second reset period (RT2) ends. The reset signal (RST) may be maintained at a low level in the second reference signal readout period (RO2_REF).

The transfer signal (TS) may have a high level during at least a portion of the first reset period (RT1). In the period in which the transfer signal (TS) and the reset signal (RST) have high levels at the same time, the photoelectric conversion element (PD) may be reset to the power-supply voltage (VDD).

The transfer signal (TS) may transition from a high level to a low level before the first reference signal readout period (RO1_REF) ends. For example, the transfer signal (TS) may transition from a high level to a low level when the first reset period (RT1) ends.

The transfer signal (TS) may transition again from a low level to a high level before the accumulation period (INT) ends. The transfer signal (TS) having entered a high level again may transition from a high level to a low level before the first image signal readout period (RO1_PX) ends. During a predetermined time from the time at which the first reset period (RT1) ends to the other time (e.g., the time at which the accumulation period (INT) ends in the example shown in FIG. 10) at which the transfer signal (TS) transitions from a high level to a low level for the second time, photocharges generated by the photoelectric conversion element (PD) in response to incident light may move to the floating diffusion region (FD).

After the transfer signal (TS) transitions from a high level to a low level for the second time, movement of the photocharges generated by the photoelectric conversion element (PD) to the floating diffusion region (FD) may be prevented. The transfer signal (TS) may have a low level in each of the first image signal readout period (RO1_PX) and the second image signal readout period (RO2_PX).

The transfer signal (TS) may have a high level again in the second reset period (RT2). When the transfer signal (TS) has a high level again, the photoelectric conversion element (PD) may be reset to the power-supply voltage (VDD).

When the reset of the photoelectric conversion element (PD) is completed, the transfer signal (TS) may transition again from a high level to a low level, so that the transfer signal (TS) may be maintained at a low level.

The conversion gain signal (CGS) may have a high level not only in each of the first and second reference signal readout periods (RO1_REF, RO2_REF), but also in each of the first and second image signal readout periods (RO1_PX, RO2_PX). In some implementations, the conversion gain signal (CGS) may maintain a high level throughout the first reference signal readout period (RO1_REF), the accumulation period (INT), the first image signal readout period (RO1_PX), and the second image signal readout period (RO2_PX). The conversion gain signal (CGS) may have a low level in the first and second reset periods (RT1, RT2). The conversion gain signal (CGS) may have a high level again in the second image signal readout period (RO2_PX).

The first bias voltage (BV1) may have a fifth voltage (V5) in each of the first reference signal readout period (RO1_REF) and the first image signal readout period (RO1_PX). The first bias voltage (BV1) may have a sixth voltage (V6) in each of the second reference signal readout period (RO2_REF) and the second image signal readout period (RO2_PX).

In some implementations, the first bias voltage (BV1) may transition from the fifth voltage (V5) to the sixth voltage (V6) when moving from the first image signal readout period (RO1_PX) to the second image signal readout period (RO2_PX). Such transition from the fifth voltage (V5) to the sixth voltage (V6) may be performed gradually.

The second bias voltage (BV2) may be at the second voltage (V2) in each of the first reference signal readout period (RO1_REF) and the first image signal readout period (RO1_PX). The second bias voltage (BV2) may have a third voltage (V3) in each of the second reference signal readout period (RO2_REF) and the second image signal readout period (RO2_PX).

In some implementations, the second bias voltage (BV2) may transition from the second voltage (V2) to the third voltage (V3) when moving from the first image signal readout period (RO1_PX) to the second image signal readout period (RO2_PX). Such transition from the second voltage (V2) to the third voltage (V3) may be performed gradually.

In response to the conversion gain signal (CGS), the first bias voltage (BV1) and the second bias voltage (BV2), the conversion gain of the unit pixel (PX) may be the second conversion gain (CG2) in each of the first reference signal readout period (RO1_REF) and the first image signal readout period (RO1_PX). The conversion gain of the unit pixel (PX) may be the third conversion gain (CG3) in each of the second reference signal readout period (RO2_REF) and the second image signal readout period (RO2_PX).

The row selection signal (SEL) may be at a high level not only in each of the first and second reference signal readout periods (RO1_REF, RO2_REF), but also in each of the first and second image signal readout periods (RO1_PX, RO2_PX).

When the row selection signal (SEL) reaches a high level in the first reference signal readout period (RO1_REF), the first reference signal, which is an electrical signal corresponding to the voltage of the floating diffusion region (FD) according to the second conversion gain (CG2), may be output to the readout circuit 130 through the selection transistor (SX).

In the first image signal readout period (RO1_PX), when the row selection signal (SEL) becomes a high level, the first image signal, which is an electrical signal corresponding to the voltage of the floating diffusion region (FD) according to the second conversion gain (CG2), may be output to the readout circuit 130 through the selection transistor (SX). Here, the floating diffusion region (FD) may be in a state where photocharges generated by the photoelectric conversion element (PD) are stored.

Since the row selection signal (SEL) has a high level in the second image signal readout period (RO2_PX), the second image signal, which is an electrical signal corresponding to the voltage of the floating diffusion region (FD) according to the third conversion gain (CG3), may be output to the readout circuit 130 through the selection transistor (SX). Here, the floating diffusion region (FD) may be in a state where the photocharges stored in the floating diffusion region (FD) at the time the first image signal is output are maintained.

In the second reference signal readout period (RO2_REF), when the row selection signal (SEL) becomes a high level, the second reference signal, which is an electrical signal corresponding to the voltage of the floating diffusion region (FD) according to the third conversion gain (CG3), may be output to the readout circuit 130 through the selection transistor (SX). Here, the floating diffusion region (FD) may be in a state after being reset to the power-supply voltage (VDD) in the second reset period (RT2).

The timing diagram of the respective signals according to the disclosed technology is merely an example, and the embodiment of the disclosed technology may include other examples in which the order of respective periods is also changed and implemented according to common sense in the art.

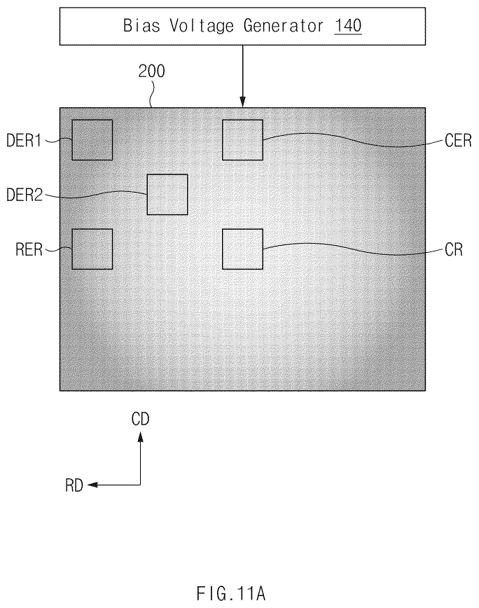

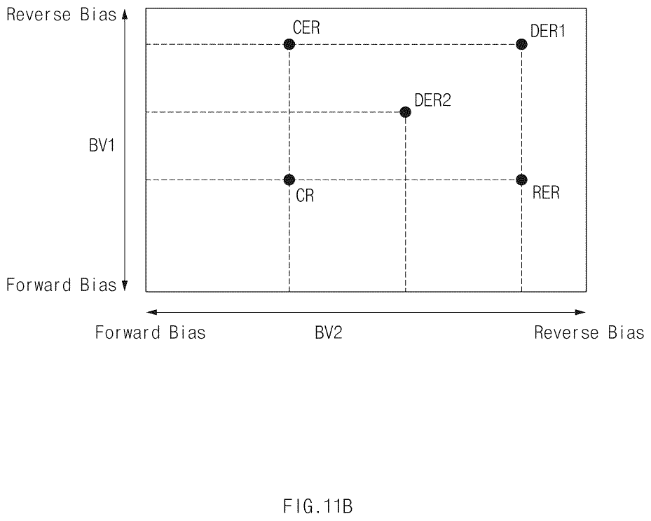

FIGS. 11A and 11B illustrate example signal lines applied to the plurality of pixels located in the pixel array 120 by the bias voltage generator 140 shown in FIG. 1 based on some embodiments of the disclosed technology.

Referring to FIGS. 1, 2, 6A, and 11A, the bias voltage generator 140 may include a first bias voltage generator and a second bias voltage generator.

The first bias voltage generator may transmit the first bias voltage (BV1) to the first diode (D1) of each pixel (PX) included in the pixel array 200 in the column direction (CD). The second bias voltage generator may transmit a second bias voltage (BV2) to the second diode (D2) of each pixel (PX) included in the pixel array 200 in the row direction (RD). Conversely, the first bias voltage generator may control the second bias voltage (BV2), and the second bias voltage generator may control the first bias voltage (BV1). Hereinafter, an embodiment in which the first bias voltage generator controls the first bias voltage (BV1) and the second bias voltage generator controls the second bias voltage (BV2) will be described in detail with reference to the attached drawings.

The pixel array 200 may include a central region (CR), a horizontal edge region (RER), a vertical edge region (CER), and a diagonal edge region (DER). The central region (CR) may be arranged near the center of the pixel array 200. The horizontal edge region (RER) may pass through the central region (CR), and may be disposed on at least one side of the central region (CR) in the row direction (or in the horizontal direction). The vertical edge region (CER) may pass through the central region (CR), and may be disposed on at least one side of the central region (CR) in the column direction (or in the vertical direction). The diagonal edge region (DER) may pass through the central region (CR), and may be disposed on at least one side of the central region (CR) in the diagonal direction. The pixel array 200 may include a plurality of pixels. The plurality of pixels may be disposed at intersection points where the column voltage supply lines (CLG1, CLG2) and the row voltage supply lines (RLG1, RLG2) cross each other.

In the pixel array 200, for example, due to a lens shading phenomenon, etc., in a certain illuminance environment, the central region (CR) may have a greater amount of incident light than the horizontal edge region (RER) or the vertical edge region (CER), and the diagonal edge region (DER) may have a smaller amount of incident light than the horizontal edge region (RER) or the vertical edge region (CER).

The first bias voltage generator may transmit the first bias voltage (BV1) to the first diodes (D1) of the pixels through a plurality of column voltage supply lines in the column direction (CD). The plurality of column voltage supply lines may include a first column voltage supply line (CLG1) and a second column voltage supply line (CLG2). The first column voltage supply line (CLG1) may transmit the first bias voltage (BV1) to the first diodes (D1) of the pixels arranged in the diagonal edge region (DER) and the vertical edge region (CER). The second column voltage supply line (CLG2) may transmit the first bias voltage (BV1) to the first diodes (D1) of the pixels arranged in the horizontal edge region (RER) and the central region (CR).

According to one embodiment for correcting the lens shading phenomenon, the total storage capacity (C_{T}) may be reduced to set the conversion gain of a pixel having a relatively small amount of incident light to a relatively high gain. According to one example of reducing the total storage capacity (C_{T}), the first bias voltage (BV1) applied to the first diode (D1) may be a reverse bias voltage, and as the magnitude of the reverse bias voltage increases, the conversion gain may increase.

For example, the magnitude of the reverse bias voltage of the first bias voltage (BV1) transmitted through the first column voltage supply line (CLG1) may be greater than the magnitude of the reverse bias voltage of the first bias voltage (BV1) transmitted through the second column voltage supply line (CLG2).

The second bias voltage generator may transmit the second bias voltage (BV2) to the second diode (D2) of each pixel through the plurality of row voltage supply lines in the row direction (RD). The plurality of row voltage supply lines may include a first row voltage supply line (RLG1) and a second row voltage supply line (RLG2). The first row voltage supply line (RLG1) may transmit the second bias voltage (BV2) to the second diodes (D2) of the pixels arranged in each of the diagonal edge region (DER) and the vertical edge region (CER). The second row voltage supply line (RLG2) may transmit the second bias voltage (BV2) to the second diodes (D2) of the pixels arranged in each of the horizontal edge region (RER) and the central region (CR).

According to one embodiment for correcting the lens shading phenomenon, the second bias voltage (BV2) applied to the second diode (D2) may be a reverse bias voltage, and as the magnitude of the reverse bias voltage increases, the conversion gain may increase.

For example, the magnitude of the reverse bias voltage of the second bias voltage (BV2) transmitted through the first row voltage supply line (RLG1) may be greater than the magnitude of the reverse bias voltage of the second bias voltage (BV2) transmitted through the second row voltage supply line (RLG2).

That is, the pixel located in the diagonal edge region (DER) may output a pixel signal with a conversion gain that is set higher than pixels located in each of the vertical edge region (CER), the horizontal edge region (RER), and the central region (CR). The pixel located in the vertical edge region (CER) or the horizontal edge region (RER) may output a pixel signal with a conversion gain that is set lower than pixels located in the diagonal edge region (DER), and may output a pixel signal with a conversion gain that is set relatively higher than pixels located in the central region (CR). As a result, it is possible to adjust the deviation in the amount of incident light due to the lens shading phenomenon.

Compared to the example case in which only one diode is used, the embodiments in which two diodes are used may provide the image sensing device 10 that can easily correct the lens shading phenomenon. In more detail, the image sensing device 10 according to the embodiments is configured such that bias voltages of different diodes are adjusted differently in each of the column direction (CD) and the row direction (RD) of the pixel array 200, so that the target total storage capacity (C_{T}) or the target conversion gain is properly adjusted according to the first and second bias voltages (BV1, BV2) as shown in FIG. 6A, and thus the lens shading phenomenon can be easily corrected.

As is apparent from the above description, the embodiments of the disclosed technology can provide an image sensing device having various conversion gains.

The image sensing device according to the embodiments of the disclosed technology can reduce unnecessary fluctuations in pixel signals due to changes in conversion gain when setting various conversion gains for generating HDR images.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a pixel array including a plurality of pixels configured to generate an electrical signal in response to incident light,
wherein each of the plurality of pixels includes:
a photoelectric conversion element configured to generate photocharges in response to the incident light;
a floating diffusion region configured to receive and store the photocharges generated by the photoelectric conversion element;
a first diode configured to receive a first bias voltage, wherein a capacitance of the first diode is adjusted based on the first bias voltage;
a conversion gain transistor configured to selectively connect the floating diffusion region to the first diode; and
a second diode connected to the floating diffusion region configured to receive a second bias voltage, wherein a capacitance of the second diode is adjusted based on the second bias voltage.

2. The image sensing device according to claim 1, wherein the conversion gain transistor is configured to:
electrically connect the floating diffusion region to the first diode in response to the conversion gain transistor being turned on; and
electrically separate the floating diffusion region from the first diode in response to the conversion gain transistor being turned off.

3. The image sensing device according to claim 1, wherein:
the first and second bias voltages include a reverse bias voltage that is applied to each of the first diode and the second diode, respectively.

4. The image sensing device according to claim 3, wherein:
as a magnitude of the reverse bias voltage applied to the first diode increases, a total storage capacity of the floating diffusion region decreases.

5. The image sensing device according to claim 3, wherein:
as a magnitude of the reverse bias voltage applied to the second diode increases, a total storage capacity of the floating diffusion region decreases.

6. The image sensing device according to claim 1, wherein the plurality of pixels further includes:
a first pixel; and
a second pixel having a longer exposure time than the first pixel,
wherein
a conversion gain of the first pixel is greater than a conversion gain of the second pixel.

7. The image sensing device according to claim 6, wherein:
a magnitude of a reverse bias voltage applied to the first diode or the second diode of the first pixel is greater than a magnitude of a reverse bias voltage applied to the first diode or the second diode of the second pixel.

8. The image sensing device according to claim 1, wherein:
the plurality of pixels includes first to fourth pixels; and
the pixel array includes:
a central region including the first pixel;
a horizontal edge region disposed at a first side of the central region along a horizontal line passing through the central region, and including the second pixel;
a vertical edge region disposed at a second side of the central region along a vertical line passing through the central region, and including the third pixel; and
a diagonal edge region disposed at a third side of the central region along a diagonal line passing through the central region, and including the fourth pixel.

9. The image sensing device according to claim 8, wherein:
the first bias voltage includes a reverse bias voltage applied to the first diode, and a magnitude of the reverse bias voltage applied to the first diode of the first pixel is smaller than a magnitude of the reverse bias voltage applied to the first diode of the second pixel or the third pixel.

10. The image sensing device according to claim 8, wherein:
the second bias voltage includes a reverse bias voltage applied to the second diode, and a magnitude of the reverse bias voltage applied to the second diode of the first pixel is smaller than a magnitude of the reverse bias voltage applied to the second diode of the second pixel or the third pixel.

11. The image sensing device according to claim 8, wherein:
the first and second bias voltages include a first reverse bias voltage applied to the first diode and a second reverse bias voltage applied to the second diode, respectively;
a magnitude of the first reverse bias voltage applied to the first diode of the first pixel is smaller than a magnitude of the first reverse bias voltage applied to the first diode of the fourth pixel; and
a magnitude of the second reverse bias voltage applied to the second diode of the first pixel is smaller than a magnitude of the second reverse bias voltage applied to the second diode of the fourth pixel.

12. An image sensing device comprising:
a pixel array including a plurality of pixels configured to generate an electrical signal by converting photocharges generated in response to incident light, wherein each of the plurality of pixels includes first and second diodes configured to adjust a conversion gain that determines a magnitude of the electrical signal corresponding to an amount of the photocharges; and
a bias voltage generator configured to transmit a bias voltage to each of the first diode and the second diode.

13. The image sensing device according to claim 12, wherein each of the plurality of pixels further includes:
a conversion gain transistor configured to selectively connect, to the first diode, a floating diffusion region configured store photocharges generated in response to the incident light,
wherein the second diode of each of the plurality of pixels is connected to the floating diffusion region.

14. The image sensing device according to claim 13, wherein:
upon turning on the conversion gain transistor of each of the plurality of pixels, the conversion gain transistor selectively connects the floating diffusion region to the first diode; and
upon turning off the conversion gain transistor of each of the plurality of pixels is turned off, the conversion gain transistor electrically separates the floating diffusion region from the first diode.

15. The image sensing device according to claim 14, wherein:
the bias voltage generator is configured to transmit a reverse bias voltage to each of the first and second diodes,
wherein:
as a magnitude of the reverse bias voltage increases, the conversion gain increases; and
as a magnitude of the reverse bias voltage decreases, the conversion gain decreases.

16. The image sensing device according to claim 12, wherein:
the plurality of pixels includes first to fourth pixels; and
the pixel array includes:
a central region including the first pixel;
a horizontal edge region disposed at a first side of the central region along a horizontal line passing through the central region, and including the second pixel;
a vertical edge region disposed at a second side of the central region along a vertical line passing through the central region, and including the third pixel; and
a diagonal edge region disposed at a third side of the central region along a diagonal line passing through the central region, and including the fourth pixel.

17. The image sensing device according to claim 16, wherein the bias voltage generator is configured to:
apply a stronger reverse bias voltage to the first diode of either the second pixel or the third pixel than a reverse bias voltage applied to the first diode of the first pixel.

18. The image sensing device according to claim 16, wherein the bias voltage generator is configured to apply a stronger reverse bias voltage to the second diode of either the second pixel or the third pixel than a reverse bias voltage applied to the second diode of the first pixel.

19. The image sensing device according to claim 16, wherein the bias voltage generator is configured to:
apply a stronger reverse bias voltage to the first diode of the fourth pixel than a reverse bias voltage applied to the first diode of the first pixel; and
apply a stronger reverse bias voltage to the second diode of the fourth pixel than a reverse bias voltage applied to the second diode of the first pixel.
